(19) United States
(12) Patent Application Publication
(10) Pub. No.: US 2019/0031790 A1
(43) Pub. Date: Jan. 31, 2019

(54) PHOTOSENSITIVE RESIN COMPOSITION, DRY FILM USING SAME, PRINTED WIRING BOARD, AND METHOD FOR MANUFACTURING PRINTED WIRING BOARD

(71) Applicant: HITACHI CHEMICAL COMPANY, LTD., Tokyo (JP)

(72) Inventors: Nobuhito KOMURO, Hitachi-shi, Ibaraki (JP); Yuta DAIJIMA, Kamisu-shi, Ibaraki (JP)

(21) Appl. No.: 16/069,234

(22) PCT Filed: Jan. 12, 2017
(86) PCT No.: PCT/JP2017/000782

§ 371 Date: Jul. 11, 2018

(30) Foreign Application Priority Data
Jan. 12, 2016 (JP) 2016-003925

(51) Int. Cl. C08F 2/48; C08F 290/06; G03F 7/027; H05K 3/28

(52) U.S. Cl. CPC C08F 2/48; H05K 3/28; G03F 7/027; C08F 290/06

(57) ABSTRACT

Provided is a photosensitive resin composition: which has basic performance such as electrical insulation, soldering heat resistance, thermal shock resistance, solvent resistance, acid resistance, and alkali resistance required in a photosensitive resin composition used to produce a printed wiring board; which may form a resist shape having excellent linearity in the contours of the resist pattern because it is difficult to generate undercutting in which the bottom part is washed away or defects in the upper part of a resist; and which has excellent adhesion to a copper substrate and excellent fluidity. Also provided are a dry film prepared by using the photosensitive resin composition, a printed wiring board, and a method for producing the printed wiring board. The photosensitive resin composition contains (A) an acid-modified vinyl group-containing epoxy resin, (B) a photopolymerization initiator, (C) an ion scavenger having at least one selected from the group consisting of Zr, Bi, Mg, and Al, and (D) a photopolymerizable compound.

### TECHNICAL FIELD

The present disclosure relates to a photosensitive resin composition, a dry film using the same, a printed wiring board, and a method for producing the printed wiring board.

### BACKGROUND ART

In the field of producing printed wiring boards, permanent mask resists are formed on the printed wiring boards. The permanent mask resist has a role of preventing corrosion of a conductor layer or maintaining electrical insulation between the conductor layers at the time of using the printed wiring board. In recent years, the permanent mask resist has also a role as a solder resist film which prevents solder from being attached to an unnecessary part of a conductor layer of a printed wiring board in a process of subjecting a semiconductor device to flip chip mounting, wire bonding mounting or the like on a printed wiring board via soldering.

In the related art, a permanent mask resist in the production of a printed wiring board is prepared by screen printing using a thermosetting resin composition or by a photographic method using a photosensitive resin composition. For example, in flexible wiring boards using mounting methods such as flip chip (FC), tape automated bonding (TAB), and chip on film (COF), a thermosetting resin paste is screen-printed and thermally cured to form a permanent mask resist, except for IC chips, electronic parts or liquid crystal display (LCD) panels, and connection wiring parts (see, for example, PTL 1).

Further, in a semiconductor package substrate such as a ball grid array (BGA) and a chip size package (CSP) mounted on an electronic part, (1) to subject a semiconductor device to flip chip mounting on a semiconductor package substrate via solder, (2) to join a semiconductor device and a semiconductor package substrate by wire bonding, or (3) to join a semiconductor package substrate on a mother board substrate by soldering, it is necessary to remove the permanent mask resist at a joint part thereof. Therefore, a photographic method for forming an image by applying and drying the photosensitive resin composition and then selectively irradiating the photosensitive resin composition with actinic rays such as ultraviolet rays and curing the photosensitive resin composition, and removing only the non-irradiated part by development has been used in forming this permanent mask resist. Due to the good workability of the photographic method, the photographic method is suitable for mass production, so that the photographic method is widely used for image formation of a photosensitive resin composition in the electronic material industry (see, for example, PTL 2).

### CITATION LIST

### Patent Literature

PTL 1: JP 2003-198105A

PTL 2: JP 2011-133851A

### SUMMARY OF INVENTION

### Technical Problem

However, in the case of using a photosensitive resin composition to which a pigment or a filler is added as described in PTL 2, the pigment or the filler interferes with the transmission of ultraviolet rays or absorbs ultraviolet rays, so that when it is attempted to form a thick permanent mask resist having a thickness of 10 μm or more, photocuring of the photosensitive resin composition at the bottom part may not be sufficiently obtained in some cases, and as a result, undercutting in which the bottom part is washed away after development (see the left side of FIG. 2) may occur in some cases.

Increasing the exposure amount of ultraviolet irradiation to improve the photocurability of the bottom part increases the optical diffraction and trailing (halation) accordingly, so that the line width of the middle part (center part) and the deepest part (bottom part) becomes large with respect to the line width of the surface part (upper part) of the resist pattern cross section. Therefore, the resist shape may deteriorate, or the resolution may be lowered in some cases. In addition, due to oxygen inhibition, photocuring is insufficient in a region of about 3 μm from the surface in a resist depth direction, so that trailing (halation) in which the upper part of the resist pattern is missing and the bottom part remains may occur in some cases. Furthermore, due to oxygen inhibition, thickening in which the upper part and the bottom part of the resist pattern are missing (diffraction) and the like occur, so that the resist shape may deteriorate in some cases (see the middle and the right in FIG. 2).

Further, in recent years, with the miniaturization and high performance of electronic equipment, the size of the hole diameter of the permanent mask resist and the distance between the centers of the holes tend to be finer, so that for example, a fine pattern is used in which the size of the hole diameter is 100 μm, the distance between the centers of the holes is 100 μm, the size of the hole diameter is 80 μm, and the distance between the centers of the holes is 80 μm. In addition, in flip chip mounting, recently, in addition to improving resolution, improvement of adhesion to a copper substrate and fluidity has been required for a photosensitive resin composition.

When the permanent mask resist is formed by using the photosensitive resin composition, in the case where the adhesion to the copper substrate is not sufficient, the plating solution penetrates from the region and thus may affect the insulation reliability in some cases.

Further, when finer wirings (also referred to as “conductor patterns”) are formed, it is effective to perform application or lamination under high temperature conditions in order to uniformly flow the photosensitive resin composition. However, the case of applying or laminating under high temperature conditions increases the risk of residue generation. For this reason, it is required to have fluidity to uniformly flow the photosensitive resin composition without requiring high temperature conditions.

An object of the present disclosure is to provide a photosensitive resin composition in which it is difficult to generate undercutting in which the bottom part of a resist pattern is washed away and defects in the upper part of the resist pattern, the line width of the middle part (center part) and the deepest part (bottom part) of the resist pattern cross section hardly becomes large with respect to the line width of the surface part (that is, the linearity in the contours of the resist pattern is good), a resist pattern having an excellent resist shape may be formed, and further, adhesion to a copper substrate and fluidity are excellent, a dry film using the same, a printed wiring board, and a method for producing a printed wiring board.

### Solution to Problem

As a result of intensive studies to solve the problems, the present inventors have found that the problems may be solved by the following inventions. That is, the present disclosure provides the following photosensitive resin composition, a dry film using the same, a printed wiring board, and a method for producing a printed wiring board.

[1] A photosensitive resin composition containing (A) an acid-modified vinyl group-containing epoxy resin, (B) a photopolymerization initiator, and (C) an ion scavenger having at least one selected from the group consisting of Zr, Bi, Mg, and Al, and (D) a photopolymerizable compound.

[2] The photosensitive resin composition described in [1], in which the component (A) contains (Al) at least one acid-modified vinyl group-containing epoxy resin obtained by using a bisphenol novolac type epoxy resin (a1), and (A2) at least one acid-modified vinyl group-containing epoxy resin obtained by using an epoxy resin (a2) different from the epoxy resin (a1).

[3] The photosensitive resin composition described in [2], in which the epoxy resin (a2) is at least one selected from the group consisting of a novolac type epoxy resin, a bisphenol A type epoxy resin, a bisphenol F type epoxy resin, and a triphenol methane type epoxy resin.

[4] The photosensitive resin composition described in [2] or [3], in which the acid-modified vinyl group-containing epoxy resins (A1) and (A2) are resins obtained by allowing a saturated or unsaturated group-containing polybasic acid anhydride to react with resins (A1′) and (A2′) obtained by allowing a vinyl group-containing monocarboxylic acid (b) to react with the epoxy resins (a1) and (a2), respectively.

[5] The photosensitive resin composition described in any one of [2] to [4], in which the bisphenol novolac type epoxy resin (a1) has a structural unit represented by the following general formula (I) or (II):

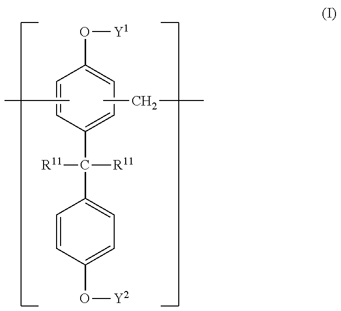

wherein R¹¹ represents a hydrogen atom or a methyl group, and Y¹ and Y² each independently represent a hydrogen atom or a glycidyl group, provided that plural R¹¹'s are the same or different and at least one of Y¹ and Y² represents a glycidyl group:

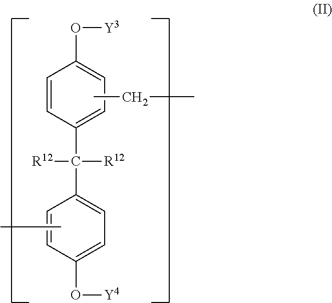

wherein R¹² represents a hydrogen atom or a methyl group, and Y³ and Y⁴ each independently represent a hydrogen atom or a glycidyl group, provided that plural R¹²'s are the same or different and at least one of Y³ and Y⁴ represents a glycidyl group.

[6] The photosensitive resin composition described in any one of [2] to [5], in which the bisphenol novolac type epoxy resin (a1) has a structural unit represented by general formula (I), and the epoxy resin (a2) is a bisphenol A type epoxy resin or a bisphenol F type epoxy resin, which contains a structural unit represented by the following general formula (IV):

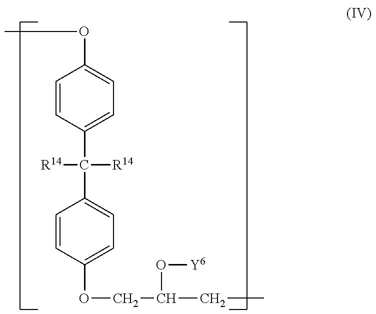

wherein R¹⁴ represents a hydrogen atom or a methyl group, Y⁶ represents a hydrogen atom or a glycidyl group, and plural R¹⁴'s are the same or different.

[7] The photosensitive resin composition described in [1], in which the component (A) contains at least one acid-modified vinyl group-containing epoxy resin (A2) obtained by using an epoxy resin (a2) different from a bisphenol novolac type epoxy resin (a1).

[8] The photosensitive resin composition described in [7], in which the acid-modified vinyl group-containing epoxy resin (A2) is a resin obtained by allowing a saturated or unsaturated group-containing polybasic acid anhydride (c) to react with a resin (A2′) obtained by allowing a vinyl group-containing monocarboxylic acid (b) to react with the epoxy resin (a2).

[9] The photosensitive resin composition described in [7] or [8], in which the epoxy resin (a2) is a novolac type epoxy resin having a structural unit represented by general formula (III):

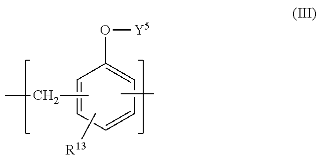

wherein R¹³ represents a hydrogen atom or a methyl group, and Y⁵ represents a hydrogen atom or a glycidyl group.

[10] The photosensitive resin composition described in any one of [1] to [9], in which the photopolymerization initiator (B) is at least one selected from the group consisting of an alkylphenone-based photopolymerization initiator, a compound having a thioxanthone skeleton (thioxanthone-based photopolymerization initiator), and an acylphosphine oxide-based photopolymerization initiator.

[11] The photosensitive resin composition described in any one of [1] to [10], in which the ion scavenger (C) is at least one selected from the group consisting of an inorganic ion exchanger that captures cations, an inorganic ion exchanger that captures anions, and an inorganic ion exchanger that captures cations and anions.

[12] The photosensitive resin composition described in any one of [1] to [11], in which the photopolymerizable compound (D) is a compound containing a (meth)acryloyl group.

[13] The photosensitive resin composition described in any one of [1] to [12], further containing (E) a pigment.

[14] The photosensitive resin composition described in any one of [1] to [13], further containing (F) an inorganic filler.

[15] The photosensitive resin composition described in any one of [1] to [14], in which the contents of the acid-modified vinyl group-containing epoxy resin (A), the photopolymerization initiator (B), the ion scavenger (C), and the photopolymerizable compound (D) are from 20 to 80% by mass, from 0.2 to 15% by mass, from 0.1 to 10% by mass, and from 0.1 to 10% by mass, respectively, based on a total solid content in the photosensitive resin composition.

[16] A dry film including a carrier film and a photosensitive layer prepared by using the photosensitive resin composition described in any one of [1] to [15].

[17] A printed wiring board including a permanent mask resist formed by the photosensitive resin composition described in any one of [1] to [15].

[18] The printed wiring board described in [17], in which the permanent mask resist has a thickness of 10 μm or more.

[19] A method for producing a printed wiring board, the method including, in the following order: providing a photosensitive layer on a substrate by using the photosensitive resin composition described in any one of [1] to [15] or the dry film described in [16]; forming a resist pattern by using the photosensitive layer; and curing the resist pattern to thereby form a permanent mask resist.

### Advantageous Effect of Invention

According to the present disclosure, it is possible to provide a photosensitive resin composition in which it is difficult to generate undercutting in which the bottom part of a resist pattern is washed away and defects in the upper part of the resist pattern, a resist pattern having excellent linearity in the contours of the resist pattern (that is, as an excellent resist shape) may be formed, and further, adhesion to a copper substrate and fluidity are excellent, a dry film using the same, a printed wiring board, and a method producing a printed wiring board.

### BRIEF DESCRIPTION OF DRAWINGS

FIG. 1 is a schematic view illustrating a resist cross section shape having excellent linearity in the contours of a resist pattern.

FIG. 2 is a schematic view illustrating a resist cross section shape having a deteriorating linearity in the contours of a resist pattern.

### DESCRIPTION OF EMBODIMENTS

### [Photosensitive Resin Composition]

A photosensitive resin composition relating to exemplary embodiments in the present disclosure (hereinafter, simply referred to as the present exemplary embodiment in some cases) contains (A) an epoxy resin containing an acid-modified vinyl group, (B) a photopolymerization initiator, and (C) an ion scavenger having at least one selected from the group consisting of Zr, Bi, Mg, and Al, and (D) a photopolymerizable compound. In the present specification, these components are simply referred to as Component (A), Component (B), Component (C), and the like in some cases.

Since the photosensitive resin composition of the present exemplary embodiment may improve photocurability of the bottom part by having the configuration, it is difficult to generate undercutting in which the bottom part of a resist pattern is washed away and defects in the upper part of the resist pattern, and the exposure amount of ultraviolet irradiation is not increased, so that it is thought that it is possible to form a thick resist pattern having excellent linearity in the contours of the resist pattern. Further, the photosensitive resin composition of the present exemplary embodiment has excellent adhesion to a copper substrate and excellent fluidity by having the specific configuration. In addition, it is thought that the photosensitive resin composition of the present exemplary embodiment also has the excellent basic performance such as electrical insulation, soldering heat resistance, thermal shock resistance, solvent resistance, acid resistance, and alkali resistance required for the photosensitive resin composition used in the production of a printed wiring board.

Hereinafter, each component will be described.

### <(A) Epoxy Resin Containing Acid-Modified Vinyl Group>

The photosensitive resin composition of the present exemplary embodiment includes Component (A). Examples of Component (A) include a resin obtained by modifying an epoxy resin with an organic acid containing a vinyl group, for example, an epoxy resin obtained by allowing a polybasic acid anhydride containing a saturated group or an unsaturated group to react with a resin obtained by allowing an epoxy resin and a monocarboxylic acid containing a vinyl group to react with each other.

Examples of Component (A) include (A1) an acid-modified vinyl group-containing epoxy resin (hereinafter, also referred to as Component (A1)) obtained by using a bisphenol novolac type epoxy resin (a1) (hereinafter, also referred to as Component (a1)), (A2) an acid-modified vinyl group-containing epoxy resin (hereinafter, also referred to as Component (A2)) obtained by using an epoxy resin (a2) (hereinafter, also referred to as Component (a2)) other than the epoxy resin (a1), and the like. Component (A) may be used either alone or in combination of two or more thereof. Further, from the viewpoint of improving the linearity in the contours of the resist pattern, the adhesion to a copper substrate, and the fluidity because it is difficult to generate undercutting and defects in the upper part of the resist, Component (A) may be a component containing at least one type of Component (A1) and at least one type of Component (A2), a component containing one type of Component (A1) and one type of Component (A2), a component containing one type of Component (A1) or one type of Component (A2), or a component containing one type of Component (A2).

(Epoxy Resin (a1))

As Component (A), from the viewpoint of improving the linearity in the contours of the resist pattern, the adhesion to a copper substrate, and the fluidity because it is difficult to generate undercutting and defects in the upper part of the resist, and furthermore, from the viewpoint of reducing the warpage (warpage reduction properties) of a thin film substrate and improving the thermal shock resistance and the resolution, it is preferred to contain Component (A1) obtained by using Component (a1). From the same viewpoint as this, as Component (a1), a bisphenol novolac type epoxy resin having a structural unit represented by the following general formula (I) or (II) is preferred, and the bisphenol novolac type epoxy resin having the structural unit represented by general formula (II) is more preferred.

### [Epoxy Resin Having Structural Unit Represented by General Formula (I)]

One preferred aspect of Component (a1) is an epoxy resin having a structural unit represented by the following general formula (I).

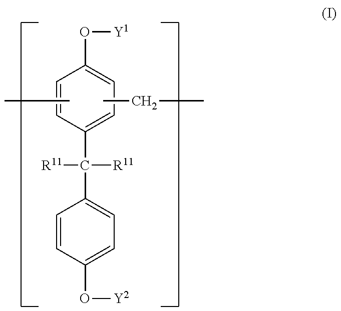

In general formula (I), R¹¹ represents a hydrogen atom or a methyl group, and Y¹ and Y² each independently represent a hydrogen atom or a glycidyl group. Plural R¹¹'s may be the same or different, and at least one of Y¹ and Y² represents a glycidyl group.

From the viewpoint of improving the linearity in the contours of the resist pattern and the resolution because it is difficult to generate undercutting and defects in the upper part of the resist, it is preferred that R¹¹ is a hydrogen atom. Further, from the viewpoint similar to this, and furthermore, from the viewpoint of improving the thermal shock resistance and the warpage reduction properties, it is preferred that Y¹ and Y² are both a glycidyl group.

The number of structural units of the structural unit in Component (a1) having the structural unit represented by general formula (I) is a number of 1 or more, and may be appropriately selected from 10 to 100, 15 to 80, or 15 to 70. When the number of structural units is within the above range, a resist shape with improved linearity in the contours of the resist pattern may be formed, and adhesion to a copper substrate, heat resistance, and electrical insulation are improved. Here, the number of structural units of the structural unit indicates an integer value in a single molecule, and indicates a rational number which is an average value in an aggregate of a plurality of molecules. Hereinafter, the same will apply to the number of structural units of the structural unit.

### [Epoxy Resin Having Structural Unit Represented by General Formula (II)]

Further, one preferred aspect of Component (a1) is an epoxy resin having a structural unit represented by the following general formula (II).

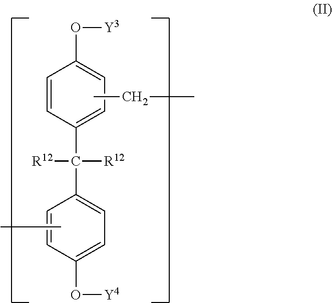

In general formula (II), R¹² represents a hydrogen atom or a methyl group, and Y³ and Y⁴ each independently represent a hydrogen atom or a glycidyl group. Plural R¹²'s may be the same or different, and at least one of Y³ and Y⁴ represents a glycidyl group.

From the viewpoint of improving the linearity in the contours of the resist pattern and the resolution because it is difficult to generate undercutting and defects in the upper part of the resist, it is preferred that R¹² is a hydrogen atom.

Further, from the viewpoint similar to this, and furthermore, from the viewpoint of improving the thermal shock resistance and the warpage reduction properties, it is preferred that Y³ and Y⁴ are both a glycidyl group.

The number of structural units of the structural unit in Component (a1) having the structural unit represented by general formula (II) is a number of 1 or more, and may be appropriately selected from 10 to 100, 15 to 80, or 15 to 70. When the number of structural units is within the above range, a resist shape with improved linearity in the contours of the resist pattern may be formed, and adhesion to a copper substrate, heat resistance, and electrical insulation are improved.

In general formula (II), an epoxy resin in which R¹² is a hydrogen atom and Y³ and Y⁴ are a glycidyl group are EXA-7376 series (manufactured by DIC Corporation, trade name), and further, an epoxy resin in which R¹² is a methyl group and Y³ and Y⁴ are a glycidyl group is EPON SU8 series (manufactured by Mitsubishi Chemical Corporation, trade name), which are commercially available.

(Epoxy Resin (a2))

Component (a2) is not particularly limited as long as the component is an epoxy resin different from Component (a1), but from the viewpoint of improving the linearity in the contours of the resist pattern, the adhesion to a copper substrate, and the fluidity, and from the viewpoint of improving the resolution because it is difficult to generate undercutting and defects in the upper part of the resist, it is preferred that Component (a2) is at least one selected from the group consisting of a novolac type epoxy resin, a bisphenol A type epoxy resin, a bisphenol F type epoxy resin, and a triphenol methane type epoxy resin.

Preferred examples of the novolac type epoxy resin include a novolac type epoxy resin having a structural unit represented by the following general formula (III), preferred examples of the bisphenol A type epoxy resin or the bisphenol F type epoxy resin include a bisphenol A type epoxy resin or a bisphenol F type epoxy resin, having a structural unit represented by the following general formula (IV), and preferred examples of the triphenol methane type epoxy resin include a triphenol methane type epoxy resin having a structural unit represented by the following general formula (V).

It is more preferred that Component (a2) is at least one selected from the novolac type epoxy resin having the structural unit represented by general formula (III), the bisphenol A type epoxy resin having the structural unit represented by general formula (IV), and the bisphenol F type epoxy resin, and as the resin having the structural unit represented by general formula (IV), the bisphenol F type epoxy resin is preferred.

Further, from the viewpoint of achieving both of photosensitive characteristics and insulation reliability, it is preferred that component (a2) is the novolac type epoxy resin having the structural unit represented by general formula (III) without using Component (A1) obtained by using Component (a1), and from the viewpoint of improving thermal shock resistance, warpage reduction properties, and resolution, it is particularly preferred to use a combination of Component (a1) which is a bisphenol novolac type epoxy resin containing the structural unit represented by general formula (II) and Component (a2) which is a bisphenol A type epoxy resin or a bisphenol F type epoxy resin that contains the structural unit represented by general formula (IV). Here, “without using Component (A1)” means that it is substantially not contained, and that the content of Component (A1) is any one of less than 5% by mass, less than 1% by mass, or less than 0.5% by mass in the total weight of the solid content of Component (A).

### [Epoxy Resin Having Structural Unit Represented by General Formula (III)]

Preferred examples of Component (a2) include a novolac type epoxy resin having a structural unit represented by the following general formula (III), and examples of a novolac type epoxy resin having the structural unit include a novolac type epoxy resin represented by the following general formula (III′).

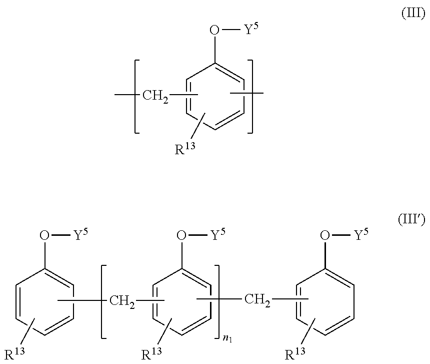

In general formula (III) or (III′), wherein R¹³ represents a hydrogen atom or a methyl group, and Y⁵ represents a hydrogen atom or a glycidyl group. Further, in general formula (III′), n₁ is a number of 1 or more, plural R¹³'s may be the same or different, plural Y⁵'s may be the same or different, and at least one of Y⁵'s represents a glycidyl group.

From the viewpoint of improving the linearity in the contours of the resist pattern and the resolution because it is difficult to generate undercutting and defects in the upper part of the resist, it is preferred that R¹³ is a hydrogen atom.

For Y⁵, in general formula (III′), a molar ratio of Y⁵ which is a hydrogen atom to Y⁵ which is a glycidyl group may be appropriately selected from 0/100 to 30/70, or 0/100 to 10/90, from the viewpoint of improving the linearity in the contours of the resist pattern and the resolution because it is difficult to generate undercutting and defects in the upper part of the resist. As can be seen from this molar ratio, at least one of Y⁵'s is a glycidyl group.

n₁ is a number of 1 or more, and may be appropriately selected from 10 to 200, 30 to 150, or 30 to 100. When n₁ is within the above range, a resist shape with improved linearity in the contours of the resist pattern may be formed, and adhesion to a copper substrate, heat resistance, and electrical insulation are improved.

Examples of the novolac type epoxy resin represented by general formula (III′) include a phenol novolac type epoxy resin and a cresol novolac type epoxy resin. These novolac type epoxy resins may be obtained, for example, by allowing epichlorohydrin to react with a phenol novolac resin or a cresol novolac resin by a well-known method.

As the phenol novolac type epoxy resin or the cresol novolac type epoxy resin represented by general formula (III′), for example, YDCN-701, YDCN-702, YDCN-703, YDCN-704, YDCN-704L, YDPN-638, and YDPN-602 (all manufactured by Nippon Steel Chemical Co., Ltd., trade name), DEN-431 and DEN-439 (all manufactured by The Dow Chemical Company, trade name), EOCN-120, EOCN-102S, EOCN-103S, EOCN-104S, EOCN-1012, EOCN-1025, EOCN-1027, and BREN (all manufactured by Nippon Kayaku, Co., Ltd., trade name), EPN-1138, EPN-1235, and EPN-1299 (all manufactured by BASF Inc., trade name), N-730, N-770, N-865, N-665, N-673, VH-4150, and VH-4240 (all manufactured by DIC Corporation, trade name), and the like are commercially available.

### [Epoxy Resin Having Structural Unit Represented by General Formula (IV)]

Preferred examples of Component (a2) include a bisphenol A type epoxy resin or a bisphenol F type epoxy resin, having a structural unit represented by the following general formula (IV), and examples of an epoxy resin having the structural unit include a bisphenol A type epoxy resin or bisphenol F type epoxy resin represented by general formula (IV′).

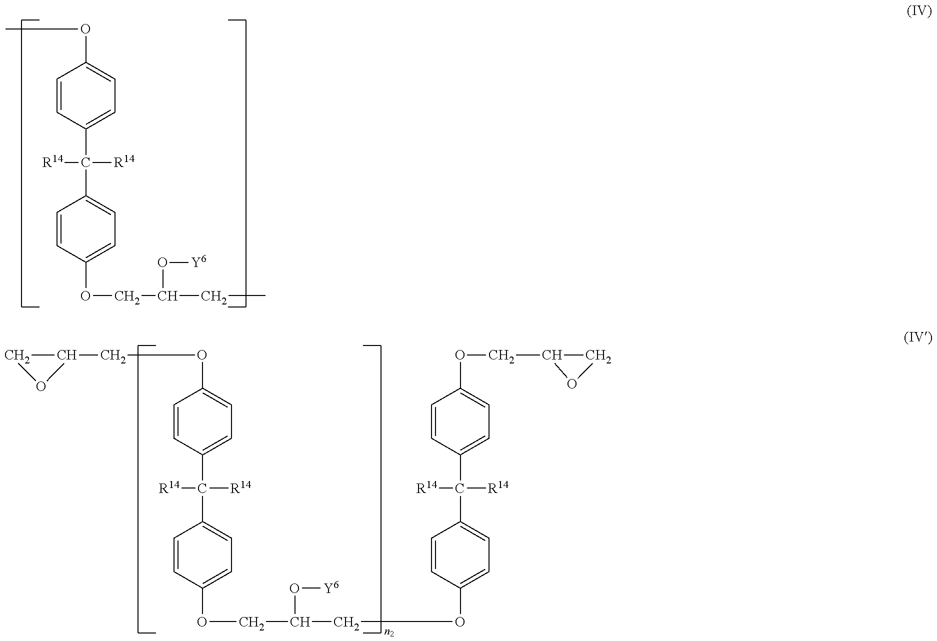

In general formulae (IV) and (IV′), R¹⁴ represents a hydrogen atom or a methyl group, and Y⁶ represents a hydrogen atom or a glycidyl group. Further, plural R¹⁴'s may be the same or different, in general formula (IV′), n₂ represents a number of 1 or more, and when n₂ is 2 or more, plural Y⁶'s may be the same or different and at least one of Y⁶'s is a glycidyl group.

From the viewpoint of improving the linearity in the contours of the resist pattern and the resolution because it is difficult to generate undercutting and defects in the upper part of the resist, it is preferred that R¹⁴ is a hydrogen atom.

Further, from the viewpoint similar to this, and furthermore, from the viewpoint of improving the thermal shock resistance and the warpage reduction properties, it is preferred that Y⁶ is a glycidyl group.

n₂ represents a number of 1 or more and may be appropriately selected from 10 to 100, 10 to 80, or 15 to 60. When n₂ is within the above range, a resist shape with improved linearity in the contours of the resist pattern may be formed, and adhesion to a copper substrate, heat resistance, and electrical insulation are improved.

The bisphenol A type epoxy resin or bisphenol F type epoxy resin represented by general formula (IV) in which Y⁶ is a glycidyl group may be obtained, for example, by allowing epichlorohydrin to react with a hydroxy group (—OY⁶) of the bisphenol A type epoxy resin or bisphenol F type epoxy resin represented by general formula (IV) in which Y⁶ is a hydrogen atom.

In order to accelerate the reaction between the hydroxy group and epichlorohydrin, it is preferred to carry out the reaction in a polar organic solvent such as dimethylformamide, dimethylacetamide, and dimethylsulfoxide in the presence of an alkali metal hydroxide at a reaction temperature of 50 to 120° C. When the reaction temperature is within the above range, the reaction does not become too slow, so that side reactions may be suppressed.

As the bisphenol A type epoxy resin or bisphenol F type epoxy resin represented by general formula (IV′), for example, jER807, jER815, jER825, jER827, jER828, jER834, jER1001, jER1004, jER1007, and jER1009 (all manufactured by Mitsubishi Chemical Corporation, trade name), DER-330, DER-301, and DER-361 (all manufactured by The Dow Chemical Company, trade name), YD-8125, YDF-170, YDF-170, YDF-175S, YDF-2001, YDF-2004, and YDF-8170 (manufactured by Nippon Steel Chemical Co., Ltd., trade name), and the like are commercially available.

### [Epoxy Resin Having Structural Unit Represented by General Formula (V)]

Preferred examples of Component (a2) include a triphenol methane type epoxy resin having a structural unit represented by the following general formula (V), and preferred examples of a triphenol methane type epoxy resin having the structural unit include a triphenol methane type epoxy resin represented by the following general formula (V′).

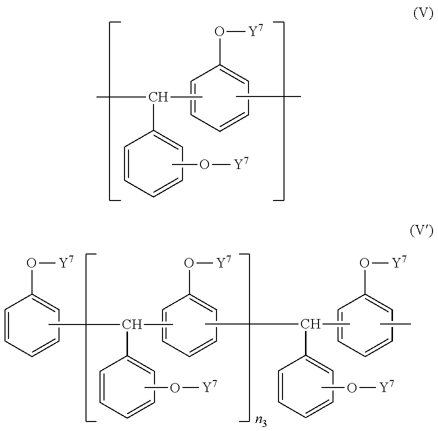

In general formulae (V) and (V′), Y⁷ represents a hydrogen atom or a glycidyl group, plural Y⁷'s may be the same or different, and at least one of Y⁷'s is a glycidyl group. Furthermore, in general formula (V′), n₃ represents a number of 1 or more.

For y⁷, a molar ratio of Y⁷ which is a hydrogen atom to Y⁷ which is a glycidyl group may be appropriately selected from 0/100 to 30/70 from the viewpoint of improving the linearity in the contours of the resist pattern and the resolution because it is difficult to generate undercutting and defects in the upper part of the resist. As can be seen from this molar ratio, at least one of Y⁷'s is a glycidyl group.

n₃ represents a number of 1 or more and may be appropriately selected from 10 to 100, 15 to 80, or 15 to 70. When n₃ is within the above range, a resist shape with improved linearity in the contours of the resist pattern may be formed, and adhesion to a copper substrate, heat resistance, and electrical insulation are improved.

As the triphenol methane type epoxy resin represented by general formula (V′), for example, FAE-2500, EPPN-501H, and EPPN-502H (all manufactured by Nippon Kayaku Co., Ltd., trade name), and the like are commercially available.

From the viewpoint of improving the linearity in the contours of the resist pattern and the resolution, it is preferred that Component (A1) and Component (A2) are a resin obtained by allowing the polybasic acid anhydride containing a saturated or unsaturated group (c) (hereinafter, also referred to as Component (c)) to react with Resins (A1′) and (A2′) (hereinafter, collectively referred to as “Component (A′)” in some cases) obtained by allowing Component (a1) and Component (a2)(hereinafter, referred to as “Component (a)” in some cases) to react with the monocarboxylic acid containing a vinyl group (b) (hereinafter, also referred to as Component (b)).

[Monocarboxylic Acid Containing Vinyl Group (b)]

Preferred examples of Component (b) include acrylic acid derivatives such as acrylic acid, a dimer of acrylic acid, methacrylic acid, β-furfuryl acrylic acid, β-styryl acrylic acid, cinnamic acid, crotonic acid, and α-cyano cinnamic acid, a half ester compound which is a reaction product of an acrylate containing a hydroxy group and a dibasic acid anhydride, a half ester compound which is a reaction product of a monoglycidyl ether containing a vinyl group or a monoglycidyl ester containing a vinyl group and a dibasic acid anhydride, and the like.

The half ester compound is obtained, for example, by allowing a dibasic acid anhydride to react with an acrylate containing a hydroxy group, a monoglycidyl ether containing a vinyl group or a monoglycidyl ester containing a vinyl group at an equimolar ratio. Component (b) may be used either alone or in combination of two or more thereof.

Examples of the acrylate containing a hydroxy group, the monoglycidyl ether containing a vinyl group, and the monoglycidyl ester containing a vinyl group used for the synthesis of the half ester compound which is an example of Component (b) include hydroxyethyl acrylate, hydroxyethyl methacrylate, hydroxypropyl acrylate, hydroxypropyl methacrylate, hydroxybutyl acrylate, hydroxybutyl methacrylate, polyethylene glycol monoacrylate, polyethylene glycol monomethacrylate, trimethylolpropane diacrylate, trimethylolpropane dimethacrylate, pentaerythritol triacrylate, pentaerythritol trimethacrylate, dipentaerythritol pentaacrylate, pentaerythritol pentamethacrylate, glycidyl acrylate, and glycidyl methacrylate.

Examples of the dibasic acid anhydride used for the synthesis of the half ester compound include those containing a saturated group, and those containing an unsaturated group. Specific examples of the dibasic acid anhydride include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride.

In the reaction of Component (a) with Component (b), the reaction is preferably carried out in such a ratio that the amount of Component (b) is preferably 0.6 to 1.05 equivalent weights, and more preferably 0.8 to 1.0 equivalent weight based on 1 equivalent weight of the epoxy group of Component (a). Reaction at such a ratio improves the photopolymerizability, that is, increases the photosensitivity, so that the linearity in the contours of the resist pattern is improved.

Components (a) and (b) may be dissolved in an organic solvent and reacted.

Preferred examples of the organic solvent include ketones such as methyl ethyl ketone and cyclohexanone; aromatic hydrocarbons such as toluene, xylene and tetramethylbenzene; glycol ethers such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; esters such as ethyl acetate, butyl acetate, butyl cellosolve acetate, and carbitol acetate; aliphatic hydrocarbons such as octane and decane; petroleum-based solvents such as petroleum ether, petroleum naphtha, hydrogenated petroleum naphtha, and solvent naphtha; and the like.

Furthermore, it is preferred to use a catalyst in order to accelerate the reaction of Component (a) and Component (b). Examples of the catalyst include triethylamine, benzylmethylamine, methyltriethylammonium chloride, benzyltrimethylammonium chloride, benzyltrimethylammonium bromide, benzyltrimethylammonium iodide, and triphenylphosphine.

The amount of catalyst used may be appropriately selected from 0.01 to 10 parts by mass, 0.05 to 2 parts by mass, or 0.1 to 1 part by mass based on 100 parts by mass of the total of Components (a) and (b). With the amount used, the reaction of Component (a) and Component (b) is accelerated.

Further, for the purpose of preventing polymerization during the reaction, it is preferred to use a polymerization inhibitor. Examples of the polymerization inhibitor include hydroquinone, methylhydroquinone, hydroquinone monomethyl ether, catechol, and pyrogallol.

The amount of polymerization inhibitor used may be appropriately selected from 0.01 to 1 part by mass, 0.02 to 0.8 parts by mass, or 0.04 to 0.5 parts by mass based on 100 parts by mass of the total of Components (a) and (b) from the viewpoint of improving the storage stability of the composition.

The reaction temperature of Component (a) and Component (b) may be appropriately selected from 60 to 150° C., 80 to 120° C., or 90 to 110° C., from the viewpoint of productivity.

As described above, it is inferred that Component (A′) obtained by allowing Component (a) and Component (b) to react with each other has a hydroxy group obtained by a ring-opening addition reaction of an epoxy group of Component (a) and a carboxy group of Component (b).

It is inferred that the hydroxy group of Component (A′) (also including the hydroxy group originally present in Component (a)) and the acid anhydride group of Component (c) are also formed of an epoxy resin containing an acid-modified vinyl group which is half esterified by allowing Component (c) containing a saturated or unsaturated group to react with Component (A′) obtained above.

[Polybasic Acid Anhydride (c)]

As Component (c), one containing a saturated group or one containing an unsaturated group may be used. Specific examples of Component (c) include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride. Among them, tetrahydrophthalic anhydride is preferred from the viewpoint of obtaining a photosensitive resin composition capable of forming a pattern excellent in resolution.

In the reaction of Component (A′) and Component (c), for example, the acid value of the epoxy resin containing an acid-modified vinyl group may be adjusted by allowing 0.1 to 1.0 equivalent weight of Component (c) to react with 1 equivalent weight of the hydroxy group in Component (A′).

The acid value of Component (A) may be 30 to 150 mgKOH/g, 40 to 120 mgKOH/g, or 50 to 100 mgKOH/g. When the acid value is 30 mgKOH/g or more, the solubility of the photosensitive resin composition in a dilute alkali solution is excellent, and when the acid value is 150 mgKOH/g or less, the electrical characteristics of the cured film are improved.

The reaction temperature of Component (A′) and Component (c) may be appropriately selected from 50 to 150° C., 60 to 120° C., or 70 to 100° C., from the viewpoint of productivity.

Further, as Component (a), for example, a hydrogenated bisphenol A type epoxy resin may be partly used in combination, if necessary. In addition, as Component (A), a styrene-maleic acid-based resin such as a hydroxyethyl(meth)acrylate modified product of a styrene-maleic anhydride copolymer may also be partly used in combination.

### (Molecular Weight of Component (A))

The weight average molecular weight of Component (A) may be 3,000 to 30,000, 4,000 to 25,000, or 5,000 to 18,000. When the weight average molecular weight is within the above range, a resist shape with improved linearity in the contours of the resist pattern may be formed, and adhesion to a copper substrate, heat resistance, and electrical insulation are improved. Here, the weight average molecular weight is a weight average molecular weight in terms of polyethylene measured by a gel permeation chromatography (GPC) method using tetrahydrofuran as a solvent. More specifically, for example, a value obtained by measurement under the following GPC measuring apparatus and measurement conditions and converted using a calibration curve of standard polystyrene may be taken as the weight average molecular weight. Furthermore, for preparation of the calibration curve, 5 sample sets (“PStQuick MP-H” and “PStQuick B,” manufactured by Tosoh Corporation) are used as standard polystyrene.

### (GPC Measuring Apparatus)

GPC apparatus: High-speed GPC apparatus “HCL-8320 GPC,” the detector is a differential refractometer or a UV detector, manufactured by Tosoh Corporation

Column: Column TSKgel SuperMultipore HZ-H (column length: 15 cm, column inner diameter: 4.6 mm), manufactured by Tosoh Corporation

(Measurement Conditions)

Solvent: Tetrahydrofuran (THF)

Measurement temperature: 40° C.

Flow rate: 0.35 ml/min

Sample concentration: 10 mg/5 ml of THF

Injection amount: 20 μl

### (Content of Component (A))

The content of Component (A) may be appropriately selected from 20 to 80% by mass, 30 to 70% by mass, or 30 to 50% by mass based on the total solid content of the photosensitive resin composition, from the viewpoint of improving the heat resistance, electrical characteristics, and chemical resistance of the coating film. In the present specification, the “solid content” refers to a nonvolatile content excluding volatilizing substances such as water and a diluent included in the photosensitive resin composition, and indicates remaining components without being evaporated or volatilized when the resin composition is dried, and also includes components in a liquid phase, a starch syrup phase, and a waxy phase at room temperature around 25° C.

### (Total Content of Component (A1) and Component (A2) in Component (A))

When Component (A1) and Component (A2) are used in combination as Component (A), the total content of Component (A1) and Component (A2) in Component (A) may be appropriately selected from 80 to 100% by mass, 90 to 100% by mass, 95 to 100% by mass, or 100% by mass, from the viewpoint of being able to form a resist shape with improved linearity in the contours of the resist pattern and improving the electroless plating resistance and soldering heat resistance. Furthermore, even when Components (A1) and (A2) are used alone, the total content may be appropriately selected from the above range.

### (Mass Ratio of Component (A1) and Component (A2))

When Component (A1) and Component (A2) are used in combination as Component (A), the mass ratio (A1/A2) thereof may be appropriately selected from 20/80 to 90/10, 20/80 to 80/20, 30/70 to 70/30, 30/70 to 55/45, or 30/70 to 50/50, from the viewpoint of being able to form a resist shape with improved linearity in the contours of the resist pattern and improving the electroless plating resistance and soldering heat resistance.

### <(B) Photopolymerization Initiator>

Component (B) used in the present exemplary embodiment is not particularly limited as long as the component may polymerize Component (E) to be described below, and may be appropriately selected from commonly used photopolymerization initiators. Examples thereof include well known photopolymerization initiators such as an alkylphenone-based photopolymerization initiator, an acylphosphine oxide-based photopolymerization initiator, a compound having a thioxanthone skeleton, and a titanocene-based photopolymerization initiator. Among them, from the viewpoint of being able to form a resist shape with improved linearity in the contours of the resist pattern and improving the electroless plating resistance and soldering heat resistance, at least one selected from the group consisting of an alkylphenone-based photopolymerization initiator, a compound having a thioxanthone skeleton (thioxanthone-based photopolymerization initiator), and an acylphosphine oxide-based photopolymerization initiator may be used, an alkylphenone photopolymerization initiator and a compound having a thioxanthone skeleton may be used in combination, and a compound having a thioxanthone skeleton and an acylphosphine oxide-based photopolymerization initiator may be used in combination.

The alkylphenone-based photopolymerization initiator is not particularly limited as long as the photopolymerization initiator is a compound having an alkylphenone skeleton, and examples thereof include 2,2-dimethoxy-1,2-diphenylethan-1-one, 1-hydroxy-cyclohexyl phenyl ketone, 1-[4-(2-hydroxyethoxy)-phenyl]-2-hydroxy-2-methyl-1-propan-1-one, 2-hydroxy-1-{4-[4-(2-hydroxy-2-methyl-propionyl)-benzyl]phenyl}-2 -methyl-propan-1-one, phenylglyoxylic acid methyl ester, 2-methyl-1-(4-methylthiophenyl)-2-morpholinopropan-1-one, and 2-benzyl-2-dimethylamino-1-(4-morpholinophenyl)-butanon-1,2-(dimethylamino)-2-[(4-methylphenyl)methyl]-1-[4-(4-morpholinyl)phenyl]-1-butanone. The alkylphenone-based photopolymerization initiators may be used either alone or in combination of two or more thereof. As the alkylphenone-based photopolymerization initiator, 2-methyl-1-(4-methylthiophenyl)-2-morpholinopropan-1-one may be selected. Examples of the compound having a thioxanthone skeleton include 2,4-diethylthioxanthone, and 2-chlorothioxanthone. The compound having a thioxanthone skeleton may be used either alone or in combination of two or more thereof. As the compound having a thioxanthone skeleton, 2,4-diethylthioxanthone may be selected.

The acylphosphine oxide-based photopolymerization initiator is not particularly limited as long as the photopolymerization initiator is a compound having an acylphosphine oxide group (a ═P(═O)—C(═O)— group), and examples thereof include (2,6-dimethoxybenzoyl)-2,4,4-trimethylpentylphosphine oxide, 2,4,6-trimethylbenzoyldiphenylphosphine oxide, ethyl-2,4,6-trimethylbenzoylphenylphosphine oxide, bis(2,4,6-trimethylbenzoyl)phenylphosphine oxide, (2,5-dihydroxyphenyl) diphenylphosphine oxide, (p-hydroxyphenyl)diphenylphosphine oxide, bis(p-hydroxyphenyl)phenylphosphine oxide, tris(p-hydroxyphenyl)phosphine oxide, and bis(2,6-dimethoxybenzoyl)-2,4,4-trimethyl-pentylphosphine oxide. The acylphosphine oxide-based photopolymerization initiators may be used either alone or in combination of two or more thereof. As the acylphosphine oxide-based photopolymerization initiator, bis(2,4,6-trimethylbenzoyl)phenylphosphine oxide may be selected.

### (Content of Component (B))

The content of Component (B) may be appropriately selected from 0.2 to 15% by mass, 0.2 to 10% by mass, 0.4 to 5% by mass, or 0.6 to 1% by mass based on the total solid content of the photosensitive resin composition, from the viewpoint of obtaining a photosensitive resin composition capable of forming a resist shape with improved linearity in the contours of the resist pattern. Further, when the content of Component (B) is 0.2% by mass or more, it is difficult to elute an exposed part during development, and when the content is 15% by mass or less, deterioration in heat resistance is suppressed.

### <(C) Ion Scavenger>

Component (C) used in the present exemplary embodiment is an ion scavenger having at least one selected from the group consisting of zirconium (Zr), bismuth (Bi), magnesium (Mg), and aluminum (Al). The “ion scavenger” is a substance capable of capturing ions, and is not particularly limited as long as the substance has a function of capturing at least one of cations and anions. That is, the ion scavenger can also be said to be a compound having an ion capturing function. By including Component (C) having such a function, it is possible to form a resist pattern with an excellent resist shape. In addition, adhesion and fluidity tend to be improved. Furthermore, by containing Component (C), it is possible to capture and deactivate ions that affect the reliability, so that it is thought that containing Component (C) contributes to improvement in reliability, and the like. Ions captured in the present exemplary embodiment are, for example, ions such as sodium ion (Na⁺), chlorine ion (Cl⁻), bromine ion (Br), and copper ions (Cu⁺, Cu²⁺), which are allowed to react by irradiation with light, electron beams, and the like and introduced into a composition whose solubility to a solvent is changed, and electrical insulation and electrolytic corrosion resistance are improved by capturing these ions.

Examples of the ion scavenger that captures such ions include a cation scavenger that captures cations, an anion scavenger that captures anions, and an amphoteric scavenger that captures cations and anions.

### (Cation Scavenger)

Examples of the cation scavenger that captures cations include inorganic ion exchangers of metal oxides such as zirconium phosphate, zirconium tungstate, zirconium molybdate, zirconium antimonate, zirconium selenate, zirconium tellurate, zirconium silicate, zirconium phosphosilicate, and zirconium polyphosphate. Further, as these cation scavengers (also referred to as “inorganic ion exchangers”), it is possible to use IXE-100 (compound containing Zr), IXE-150 (compound containing Zr), and the like, which are commercially available from Toagosei Co., Ltd.

### (Anion Scavenger)

Examples of the anion scavenger that captures anions include inorganic ion exchangers such as bismuth oxide hydrate and hydrotalcites. In addition, as these anion scavengers (also referred to as “inorganic ion exchangers”), it is possible to use IXE-500 (compound containing Bi), IXE-530 (compound containing Bi), IXE-550 (compound containing Bi), IXE-700 (compound containing Mg and Al), IXE-700 F (compound containing Mg and Al), IXE-770D (compound containing Mg and Al), IXE-702 (compound containing Al), IXE-800 (compound containing Zr), and the like, which are commercially available from Toagosei Co., Ltd.

### (Amphoteric Scavenger)

Examples of the amphoteric scavenger that captures cations and anions include inorganic ion exchangers such as metal hydrous oxides such as aluminum oxide hydrate and zirconium oxide hydrate. Furthermore, as these amphoteric scavengers (also referred to as “inorganic ion exchangers”), it is also possible to use IXE-1320 (compound containing Mg and Al), IXE-600 (compound containing Bi), IXE-633 (compound containing Bi), IXE-680 (compound containing Bi), IXE-6107 (compound containing Zr and Bi), IXE-6136 (compound containing Zr and Bi), IXEPLAS-Al (compound containing Zr, Mg, and Al), IXEPLAS-A2 (compound containing Zr, Mg, and Al), and IXEPLAS-B1 (compound containing Zr and Bi), which are commercially available from Toagosei Co., Ltd.

In the present exemplary embodiment, the cation scavenger, the anion scavenger, and the amphoteric scavenger may be used either alone or in combination of two or more thereof as Component (C), and in consideration of simultaneously capturing cations and anions such as Na⁺, Cl⁻, Br, Cu⁺, and Cu²⁺, it is preferred to use a combination of an amphoteric scavenger and at least one of a cation scavenger and an anion scavenger, which uses the amphoteric scavenger that uses a combination of a cation scavenger and an anion scavenger.

As Component (C), those in a particle state may be used, and from the viewpoint of improving the insulation, Component (C) may be appropriately selected from an average particle diameter of 5 μm or less, 3 μm or less, or 2 μm or less. Here, the average particle diameter of Component (C) is a particle diameter of the particles dispersed in the photosensitive resin composition, and uses a value obtained by measurement as follows. First, after diluting (or dissolving) the photosensitive resin composition with methyl ethyl ketone by 1,000 times, the particles dispersed in the solvent are measured with a refractive index of 1.38 in accordance with the international standard ISO13321 by using a submicron particle analyzer (manufactured by Beckman Coulter, trade name: N5), and the particle diameter at the cumulative value of 50% (volume basis) in the particle size distribution is taken as the average particle diameter. Further, Component (C) included in a photosensitive layer provided on a carrier film or a cured film of a photosensitive resin composition is also diluted (or dissolved) by 1,000 times (volume ratio) by using a solvent as described above, and then measured by using the submicron particle analyzer.

The photosensitive resin composition of the present exemplary embodiment may contain a compound of a metal atom other than at least one selected from the group consisting of Zr, Bi, Mg, and Al as an ion scavenger. From the viewpoint of insulation reliability, the content of the ion scavenger having at least one selected from the group consisting of Zr, Bi, Mg, and Al may be appropriately selected from 80% by mass or more, 90% by mass or more, or 95% by mass or more based on the total solid content of the ion scavenger. In addition, the upper limit of the content of the ion scavenger having at least one selected from the group consisting of Zr, Bi, Mg, and Al is, for example, 100% by mass or less based on the total solid content of the ion scavenger.

### (Content of Component (C))

The content of Component (C) may be appropriately selected from 0.1 to 10% by mass, 0.1 to 5% by mass, or 0.1 to 1% by mass based on the total solid content of the photosensitive resin composition, from the viewpoint of improving the electrical insulation and electrolytic corrosion resistance.

### <(C) Photopolymerizable Compound>

Component (D) is not particularly limited as long as Component (D) is a compound having a functional group showing photopolymerizability, for example, an ethylenically unsaturated group such as a vinyl group, an allyl group, a propargyl group, a butenyl group, an ethynyl group, a phenylethynyl group, a maleimide group, a nadimide group, and a (meth) acryloyl group, and from the viewpoint of reactivity, it is preferred that Component (D) is a compound having a (meth)acryloyl group.

Preferred examples of Component (D) include hydroxyalkyl(meth)acrylates such as 2-hydroxyethyl(meth)acrylate and 2-hydroxypropyl(meth)acrylate; mono or di(meth)acrylates of a glycol such as ethylene glycol, methoxytetraethylene glycol, and polyethylene glycol; (meth) acrylamides such as N,N-dimethyl(meth)acrylamide and N-methylol(meth)acrylamide; aminoalkyl(meth)acrylates such as N,N-dimethylaminoethyl(meth)acrylate; polyhydric alcohols such as hexanediol, trimethylolpropane, pentaerythritol, ditrimethylolpropane, dipentaerythritol, and tris-hydroxyethyl isocyanurate or polyhydric(meth)acrylates of ethylene oxide or propylene oxide adducts thereof; (meth)acrylates of ethylene oxide or propylene oxide adducts of phenols such as phenoxyethyl(meth) acrylate and polyethoxydi(meth) acrylate of bisphenol A; (meth)acrylates of glycidyl ethers such as glycerin diglycidyl ether, trimethylolpropane triglycidyl ether and triglycidyl isocyanurate; melamine(meth)acrylate; and the like. Component (D) may be used either alone or in combination of two or more thereof.

In particular, Component (D) may include the polyhydric alcohol or polyhydric(meth)acrylates of ethylene oxide or propylene oxide adducts thereof, and may be the polyhydric alcohol or polyhydric(meth)acrylates of ethylene oxide or propylene oxide adducts thereof.

As Component (D), dipentaerythritol hexaacrylate may be selected.

### (Content of Component (D))

The content of Component (D) may be appropriately selected from 0.1 to 10% by mass, 0.1 to 5% by mass, or 0.3 to 3% by mass based on the total solid content in the photosensitive resin composition. When the content is 0.1% by mass or more, the tendency of the exposed part to be eluted during development may be suppressed because the photosensitivity is low, and when the content is 10% by mass or less, the deterioration in heat resistance may be suppressed.

### <(E) Pigment>

Component (E) is preferably used according to a desired color when concealing the wiring, and the like. As Component (E), a colorant which develops a desired color may be appropriately selected and used, and preferred examples thereof include a well-known colorant such as phthalocyanine blue, phthalocyanine green, iodine green, diazo yellow, crystal violet, titanium oxide, carbon black, and naphthalene black.

### (Content of Component (E))

The content of Component (E) may be appropriately selected from 0.1 to 20% by mass, 0.1 to 10% by mass, or 1 to 10% by mass based on the total solid content in the photosensitive resin composition from the viewpoint of more concealing the wiring. Furthermore, the content may be 0.1 to 5% by mass.

### <(F) Inorganic Filler>

In the photosensitive resin composition of the present exemplary embodiment, Component (F) may also be used for further improving various characteristics such as adhesion and coating film hardness.

As Component (F), it is possible to use, for example, silica (SiO₂), alumina (Al₂O₃), zirconia (ZrO₂), talc (3MgO.4SiO₂.H₂O), aluminum hydroxide (Al(OH)₃), calcium carbonate (CaCO₃) barium sulfate (BaSO₄), calcium sulfate (CaSO₄), zinc oxide (ZnO), magnesium titanate (MgO.TiO₂), carbon (C), and the like. These inorganic fillers may be used either alone or in combination of two or more thereof.

The average particle diameter of Component (F) may be appropriately selected from 0.1 to 20 μm, 0.1 to 10 μm, 0.1 to 5 μm, or 0.1 to 1 μm. When the average particle diameter is 20 μm or less, it is possible to further suppress deterioration in insulation reliability. Here, the average particle diameter of Component (F) is measured in the same manner as the measurement of the average particle diameter of Component (C).

Even in Component (F), silica may be included from the viewpoint of improving the heat resistance, and barium sulfate may be included and silica and barium sulfate may be included in combination from the viewpoint of being able to improve soldering heat resistance, crack resistance (thermal shock resistance), and adhesion strength between the underfill material and the cured film after a PCT resistance test. Furthermore, the inorganic filler may be appropriately selected from those surface-treated with alumina or an organic silane-based compound from the viewpoint of being able to improve the aggregation preventing effect.

The element composition of aluminum on the surface of the inorganic filler surface-treated with alumina or an organic silane-based compound may be appropriately selected from 0.5 to 10 atom %, 1 to 5 atom %, or 1.5 to 3.5 atom %. Further, the element composition of silicon on the surface of the inorganic filler surface-treated with an organic silane-based compound may be appropriately selected from 0.5 to 10 atom %, 1 to 5 atom %, or 1.5 to 3.5 atom %. In addition, the element composition of carbon on the surface of the inorganic filler surface-treated with an organic silane-based compound may be appropriately selected from 10 to 30 atom %, 15 to 25 atom %, or 18 to 23 atom %. These element compositions may be measured by using X-ray photoelectron spectroscopy (XPS).

As the inorganic filler surface-treated with alumina or an organic silane-based compound, for example, barium sulfate surface-treated with alumina or an organic silane-based compound, or NanoFine BFN40DC (manufactured by Nippon Solvay Co., Ltd., trade name) is commercially available.

### (Content of Component (F))

The content of Component (F) may be appropriately selected from 10 to 80% by mass, 15 to 70% by mass, 20 to 50% by mass, or 25 to 40% by mass based on the total solid content of the photosensitive resin composition. When the content is within the above range, it is possible to further improve the cured product strength, heat resistance, insulation reliability, thermal shock resistance, resolution, and the like of the photosensitive resin composition.

The content of silica when silica is used as Component (F) may be appropriately selected from 5 to 60% by mass, 15 to 55% by mass, or 15 to 50% by mass based on the total solid content of the photosensitive resin composition. Further, the content of barium sulfate when barium sulfate is used as Component (F) may be appropriately selected from 5 to 30% by mass, 5 to 25% by mass, or 5 to 20% by mass based on the total solid content of the photosensitive resin composition. When the content is within the above range, it is possible to further improve the adhesion strength between the underfill material and the cured film after the soldering heat resistance and PCT resistance tests.

### <Diluent>

A diluent may be used in the photosensitive resin composition of the present exemplary embodiment, if necessary. As the diluent, for example, an organic solvent may be used. Examples of the organic solvent include ketones such as methyl ethyl ketone and cyclohexanone, aromatic hydrocarbons such as toluene, xylene and tetramethylbenzene, glycol ethers such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether, esters such as ethyl acetate, butyl acetate, butyl cellosolve acetate, and carbitol acetate, aliphatic hydrocarbons such as octane and decane, petroleum-based solvents such as petroleum ether, petroleum naphtha, hydrogenated petroleum naphtha, and solvent naphtha, and the like.

The amount of diluent used may be appropriately selected from an amount that the total solid content in the photosensitive resin composition is 50 to 90% by mass, 60 to 80% by mass, or 65 to 75% by mass. That is, the content of the diluent in the photosensitive resin composition when the diluent is used may be appropriately selected from 10 to 50% by mass, 20 to 40% by mass, or 25 to 35% by mass. By adjusting the content within the above range, the applicability of the photosensitive resin composition is improved, so that it becomes possible to form a pattern with higher precision.

### <(G) Curing Agent>

The photosensitive resin composition of the present exemplary embodiment may include Component (G). Examples of Component (G) include a compound that is cured itself by heat, ultraviolet rays, or the like, or a compound that is cured with a carboxy group and/or a hydroxy group of Component (A) which is a photocurable component in the photosensitive resin composition of the present exemplary embodiment by heat, ultraviolet rays, or the like. By using a curing agent, heat resistance, adhesion, chemical resistance, and the like of the final cured film are improved.

Examples of Component (G) include an epoxy compound, a melamine compound, and an oxazoline compound as a thermosetting compound. Examples of the epoxy compound include a bisphenol A type epoxy resin, a bisphenol F type epoxy resin, a hydrogenated bisphenol A type epoxy resin, a brominated bisphenol A type epoxy resin, a novolac type epoxy resin, a bisphenol S type epoxy resin, a biphenyl type epoxy resin, or a heterocyclic epoxy resin such as triglycidyl isocyanurate, a bixylenol type epoxy resin, and the like. However, the epoxy compound does not contain Component (A). Examples of the melamine compound include triaminotriazine, hexamethoxymelamine, and hexabutoxylated melamine. Among them, from the viewpoint of further improving the heat resistance of the cured film, it is preferred to include an epoxy compound (epoxy resin), and it is more preferred to use an epoxy compound and a blocked isocyanate in combination.

As the blocked isocyanate, an addition reaction product of a polyisocyanate compound and an isocyanate blocking agent is used. Examples of the polyisocyanate compound include polyisocyanate compounds such as tolylene diisocyanate, xylylene diisocyanate, phenylene diisocyanate, naphthylene diisocyanate, bis(isocyanate methyl) cyclohexane, tetramethylene diisocyanate, hexamethylene diisocyanate, methylene diisocyanate, trimethyl hexamethylene diisocyanate, and isophorone diisocyanate, adduct bodies, biuret bodies, and isocyanurate bodies thereof, and the like.

Component (G) is used either alone or in combination of two or more thereof. When Component (G) is used, the content thereof may be appropriately selected from 2 to 40% by mass, 3 to 30% by mass, or 5 to 20% by mass based on the total solid content of the photosensitive resin composition. By adjusting the content within the above range, it is possible to further improve the heat resistance of a cured film to be formed while maintaining good develop ability.

In the photosensitive resin composition of the present exemplary embodiment, an epoxy resin curing agent may be used in combination for the purpose of further improving various characteristics such as heat resistance, adhesion, and chemical resistance of the final cured film.

Specific examples of the epoxy resin curing agent include imidazole derivatives such as 2-methylimidazole, 2-ethyl-4-methylimidazole, 1-benzyl-2-methylimidazole, 2-phenylimidazole, and 2-phenyl-4-methyl-5-hydroxymethylimidazole:guanamines such as acetoguanamine and benzoguanamine:polyamines such as diaminodiphenylmethane, m-phenylenediamine, m-xylenediamine, diaminodiphenylsulfone, dicyandiamide, urea, urea derivatives, melamine, and polybasic hydrazide: organic acid salts or epoxy adducts thereof amine complexes of boron trifluoride: triazine derivatives such as ethyl diamino-S-triazine and 2,4-diamino-S-triazine, and 2,4-diamino-6-xylyl-S-triazine: and the like.

The epoxy resin curing agent may be used either alone or in combination of two or more thereof, and the content of the epoxy resin curing agent in the photosensitive resin composition may be appropriately selected from 0.01 to 20% by mass, or 0.1 to 10% by mass based on the total solid content of the photosensitive resin component, from the viewpoint of improving the reliability.

### <(H) Elastomer>

The photosensitive resin composition of the present exemplary embodiment may contain Component (H). Component (H) may be suitably used particularly when the photosensitive resin composition of the present exemplary embodiment is used for a semiconductor package substrate. By adding Component (H), it is possible to suppress deterioration in flexibility and adhesive strength due to strain (internal stress) inside the resin caused by curing shrinkage of Component (A). That is, it is possible to improve the flexibility, adhesive strength, and the like of a cured film formed by the photosensitive resin composition.

Examples of Component (H) include a styrene-based elastomer, an olefin-based elastomer, a urethane-based elastomer, a polyester-based elastomer, a polyamide-based elastomer, an acrylic elastomer, and a silicone-based elastomer. These elastomers are composed of hard segment components and soft segment components, and generally, the former contributes to heat resistance and strength, and the latter contributes to flexibility and toughness.

The urethane-based elastomer is composed of a structural unit composed of a hard segment composed of a low molecular weight glycol and a diisocyanate and a soft segment composed of a polymer (long chain) diol and a diisocyanate, and examples of the polymer (long chain) diol include polypropylene glycol, polytetramethylene oxide, poly (1,4-butylene adipate), poly(ethylene-1,4-butylene adipate), polycaprolactone, poly(1,6-hexylene carbonate), and poly(1,6-hexyleneneopentylene adipate).

The number average molecular weight of the polymer (long chain) diol is preferably 500 to 10,000. In addition to ethylene glycol, a short chain diol such as propylene glycol, 1,4-butanediol, and bisphenol A may be used, and the number average molecular weight of the short chain diol is preferably 48 to 500. As a specific example of the urethane-based elastomer, PANDEX T-2185 and T-2983N (manufactured by DIC Corporation), SIRACTRAN E790, and the like are commercially available.

Examples of the polyester-based elastomer include those obtained by polycondensation of a dicarboxylic acid or a derivative thereof and a diol compound or a derivative thereof. Specific examples of the dicarboxylic acid include aromatic dicarboxylic acids such as terephthalic acid, isophthalic acid, and naphthalenedicarboxylic acid and aromatic dicarboxylic acids in which the hydrogen atoms of aromatic nuclei thereof are substituted with a methyl group, an ethyl group, a phenyl group or the like, aliphatic dicarboxylic acids having 2 to 20 carbon atoms such as adipic acid, sebacic acid, and dodecanedicarboxylic acid, alicyclic dicarboxylic acids such as cyclohexanedicarboxylic acid, and the like. These compounds may be used either alone or in combination of two or more thereof.

Specific examples of the diol compound include aliphatic diols and alicyclic diols such as ethylene glycol, 1,3-propanediol, 1,4-butanediol, 1,6-hexanediol, 1,10-decanediol and 1,4-cyclohexanediol, or a dihydric phenol represented by the following general formula (VI).

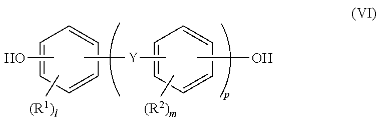

In general formula (VI), Y represents a divalent functional group selected from an alkylene group having 1 to 10 carbon atoms, a cycloalkylene group having 4 to 8 carbon atoms, and —O—, —S—, and —SO₂—, or those in which benzene rings are directly bonded to each other, R¹ and R² are a hydrogen atom, a halogen atom, or an alkyl group having 1 to 12 carbon atoms, l and m are an integer of 0 to 4, and p is 0 or 1. The alkylene group and the cycloalkylene group may be straight-chained or branched and may be substituted with a halogen atom, an alkyl group, an aryl group, an aralkyl group, an amino group, an amide group, an alkoxy group, or the like.

Specific examples of the dihydric phenol represented by general formula (VI) include bisphenol A, bis-(4-hydroxyphenyl)methane, bis-(4-hydroxy-3-methylphenyl)propane, and resorcin. These compounds may be used either alone or in combination of two or more thereof.

In addition, it is possible to use a multi-block copolymer in which the aromatic polyester (for example, polybutylene terephthalate) part is used as a hard segment component and the aliphatic polyester (for example, polytetramethylene glycol) part is used as a soft segment component. There are those with various grades depending on the type, ratio, and difference in molecular weight of the hard segment and the soft segment. Specifically, Hytrel (manufactured by Du Pont-Toray Co., Ltd., “Hytrel” is a registered trademark), Pelprene (manufactured by Toyobo Co., Ltd., “Pelprene” is a registered trademark), Espel (manufactured by Hitachi Chemical Co., Ltd., “Espel” is a registered trademark), and the like are commercially available.

For the acrylic elastomer, acrylic ester is used as a main component, ethyl acrylate, butyl acrylate, methoxyethyl acrylate, ethoxyethyl acrylate, and the like are used, and further, glycidyl methacrylate, allyl glycidyl ether, and the like are used as a crosslinking point monomer. In addition, acrylonitrile or ethylene may also be copolymerized. Specific examples thereof include an acrylonitrile butyl acrylate copolymer, an acrylonitrile butyl acrylate-ethyl acrylate copolymer, and an acrylonitrile butyl acrylate-glycidyl methacrylate copolymer.

Furthermore, in addition to the thermoplastic elastomer, a rubber-modified epoxy resin may be used. The rubber-modified epoxy resin is obtained, for example, by modifying a part or all of the epoxy groups of the bisphenol F type epoxy resin, the bisphenol A type epoxy resin, the salicylaldehyde type epoxy resin, the phenol novolac type epoxy resin or the cresol novolac type epoxy resin with a both-terminal carboxylic acid-modified butadiene-acrylonitrile rubber, a terminal amino-modified silicone rubber, or the like. Among these elastomers, preferred are a both-terminal carboxy group-modified butadiene-acrylonitrile copolymer, and Espel (manufactured by Hitachi Chemical Co., Ltd., Espel 1612, 1620) that is a polyester-based elastomer having a hydroxy group, from the viewpoint of shear adhesion.

The content of Component (H) may be appropriately selected from 2 to 40 parts by mass, 4 to 30 parts by mass, 10 to 25 parts by mass, or 15 to 22 parts by mass, based on 100 parts by mass of Component (A) (solid content). By adjusting the content within the above range, the elastic modulus of the cured film in a high temperature region becomes lower, and the unexposed part is more likely to be eluted with the developing solution.

### <Other Additives>

In the photosensitive resin composition of the present exemplary embodiment, it is possible to use various well known and commonly used additives such as a polymerization inhibitor such as hydroquinone, methylhydroquinone, hydroquinone monomethyl ether, catechol, and pyrogallol, a thickener such as bentone and montmorillonite, a silicone-based, fluorine-based, or vinyl resin-based antifoaming agent and a silane coupling agent, if necessary. Further, it is possible to use a flame retardant such as a brominated epoxy compound, an acid-modified brominated epoxy compound, an antimony compound, and a phosphorus-based compound such as a phosphate compound, an aromatic condensed phosphate ester and a condensed phosphate ester containing halogen.

In addition, the photosensitive resin composition of the present exemplary embodiment may further use (I) a triazine compound such as melamine, if necessary.

The photosensitive resin composition of the present exemplary embodiment may be obtained by uniformly kneading and mixing the blended components with a roll mill, a bead mill, or the like.

### [Dry Film]

The dry film of the present exemplary embodiment includes a carrier film and a photosensitive layer using the photosensitive resin composition of the present exemplary embodiment.

The thickness of the photosensitive layer may be appropriately selected from 10 to 50 μm, 15 to 40 μm, or 20 to 30 μm.

The dry film of the present exemplary embodiment may be produced, for example, by coating and drying the photosensitive resin composition of the present exemplary embodiment on a carrier film by a well-known method such as reverse roll coating, gravure roll coating, comma coating, and curtain coating to form a photosensitive layer.

Examples of the carrier film include polyesters such as polyethylene terephthalate and polybutylene terephthalate, and polyolefins such as polypropylene and polyethylene. The thickness of the carrier film may be appropriately selected within a range of 5 to 100 μm. Furthermore, in the dry film of the present exemplary embodiment, a protective layer may be laminated on the surface of the photosensitive layer opposite to the surface brought into contact with the carrier film. As the protective layer, for example, a polymer film such as polyethylene and polypropylene may be used. Further, a polymer film that is the same as the above-described carrier film may be used, or different polymer films may be used.

For the drying of the coating film, it is possible to use hot air drying, a drying machine using far infrared rays or near infrared rays, and the like, and the drying temperature may be appropriately selected from 60 to 120° C., 70 to 110° C., or 80 to 100° C. In addition, the drying time may be appropriately selected from 1 to 60 minutes, 2 to 30 minutes, or 5 to 20 minutes.

### [Printed Wiring Board]

The printed wiring board of the present exemplary embodiment includes a permanent mask resist formed by the photosensitive resin composition of the present exemplary embodiment.

Since the printed wiring board of the present exemplary embodiment includes the permanent mask resist formed by the photosensitive resin composition of the present exemplary embodiment, undercutting in which the bottom part is washed away neither occurs nor defects in the upper part of the resist occur, and since the line width of the middle part (center part) and the deepest part (bottom part) of the pattern cross section does not become larger than the line width of the surface part, the printed wiring board of the present exemplary embodiment has a pattern with good linearity in the contours of the pattern, an excellent resist shape, and excellent resolution. Further, the permanent mask resist has a pattern which is excellent in formation stability of the size of hole diameter which is miniaturized in accordance with recent miniaturization and high performance of electronic equipment and of interval pitch between holes.

### [Method for Producing Printed Wiring Board]

A method for producing a printed wiring board of the present exemplary embodiment includes a process of providing a photosensitive layer on a substrate by using the photosensitive resin composition of the present exemplary embodiment or the dry film of the present exemplary embodiment, a process of forming a resist pattern by using the photosensitive layer, and a process of curing the resist pattern to thereby forming a permanent mask in this order.

Specifically, for example, the printed wiring board may be produced as follows.

First, a photosensitive resin composition is applied to a film thickness appropriately selected from 10 to 200 μm, 15 to 150 μm, 20 to 100 μm, or 23 to 50 μm onto a metal clad laminated substrate such as a copper-clad laminate by a method such as a screen printing method, a spray method, a roll coating method, a curtain coating method, and an electrostatic coating method, and next, a photosensitive layer is provided on the substrate by drying the application film at 60 to 110° C. or thermally laminating the dry film of the present exemplary embodiment in which a protective layer is peeled off on the substrate by using a laminator.

Next, a negative film is brought into direct contact with the photosensitive layer (or is not brought into contact with the photosensitive layer by interposing a transparent film such as a carrier film), and actinic rays are irradiated at an exposure amount appropriately selected from 10 to 2,000 mJ/cm², 100 to 1,500 mJ/cm², or 300 to 1,000 mJ/cm², and thereafter, a resist pattern is formed by dissolving and removing (developing) the unexposed part with a dilute aqueous alkali solution. Examples of the actinic rays to be used include electron beams, ultraviolet rays, and X rays, and ultraviolet rays are preferred. In addition, as a light source, it is possible to use a low pressure mercury lamp, a high pressure mercury lamp, an extra high pressure mercury lamp, a halogen lamp, or the like.

Next, a permanent mask resist is formed by sufficiently curing the exposed part of the photosensitive layer by at least one treatment of post-exposure (ultraviolet exposure) and post-heating.

The exposure amount for post-exposure may be appropriately selected from 100 to 5,000 mJ/cm², 500 to 2,000 mJ/cm², or 700 to 1,500 J/cm².

The heating temperature for post-heating may be appropriately selected from 100 to 200° C., 120 to 180° C., or 135 to 165° C.

The heating time for post-heating may be appropriately selected from 5 minutes to 12 hours, 10 minutes to 6 hours, or 30 minutes to 2 hours.

Thereafter, a printed wiring board is produced by forming wirings by etching.

### EXAMPLES

Hereinafter, the object and advantages of the present exemplary aspect will be described in more detail based on Examples and Comparative Examples, but the present exemplary aspect is not limited to the following Examples.

### Synthesis Example 1

350 parts by mass of a bisphenol F novolac type epoxy resin (a) (EXA-7376, manufactured by DIC Corporation, a bisphenol F novolac type epoxy resin containing a structural unit in which Y³ and Y⁴ are a glycidyl group and R¹² is a hydrogen atom in general formula (II), and epoxy equivalent weight: 186), 70 parts by mass of acrylic acid (b), 0.5 parts by mass of methylhydroquinone, and 120 parts by mass of carbitol acetate were prepared and allowed to react by being heated to 90° C. and stirred, thereby completely dissolving the mixture. Next, the obtained solution was cooled to 60° C., 2 parts by mass of triphenylphosphine was added, and the resulting mixture was heated to 100° C. and allowed to react until the acid value of the solution became 1 mgKOH/g or less. 98 parts by mass of tetrahydrophthalic anhydride (THPAC) (c) and 85 parts by mass of carbitol acetate were added to the solution after the reaction, and the resulting mixture was heated to 80° C. and allowed to react for 6 hours. Thereafter, the mixture was cooled to room temperature, thereby obtaining a THPAC-modified bisphenol F novolac type epoxy acrylate (Epoxy Resin (1)) as Component (A1) having a solid content concentration of 73% by mass.

### Synthesis Example 2

1,052 parts by mass of a bisphenol F type epoxy resin (a bisphenol F type epoxy resin containing a structural unit in which Y⁶ is a hydrogen atom and R¹⁴ is a hydrogen atom in general formula (IV)) (a)(epoxy equivalent weight: 526), 144 parts by mass of acrylic acid (b), 1 part by mass of methylhydroquinone, 850 parts by mass of carbitol acetate, and 100 parts by mass of a solvent naphtha were prepared in a flask equipped with a stirrer, a reflux condenser, and a thermometer, and heated and stirred at 70° C., thereby dissolving the mixture. Next, the solution was cooled to 50° C., 2 parts by mass of triphenylphosphine, and 75 parts by mass of a solvent naphtha were prepared, heated to 100° C., and allowed to react until the solid acid value became 1 mgKOH/g or less. Next, the obtained solution was cooled to 50° C., 745 parts by mass of tetrahydrophthalic anhydride (THPAC) (c), 75 parts by mass of carbitol acetate, and 75 parts by mass of a solvent naphtha were prepared, heated to 80° C., and allowed to react for 6 hours. Thereafter, the mixture was cooled to room temperature, thereby obtaining a THPAC-modified bisphenol F type epoxy acrylate (Epoxy Resin (2)) as Component (A2) having a solid acid value of 80 mgKOH/g and a solid content of 62% by mass.

### Synthesis Example 3

220 parts by mass of a cresol novolak type epoxy resin (a) (manufactured by Tohto Kasei Co., Ltd., trade name “YDCN704,” a novolac type epoxy resin containing a structural unit in which Y⁵ is a glycidyl group and R¹³ is a methyl group in general formula (III), and epoxy equivalent weight: 206), 72 parts by mass of acrylic acid (b), 1.0 part by mass of hydroquinone, and 180 parts by mass of carbitol acetate were prepared, and heated and stirred at 90° C., thereby dissolving the reaction mixture. Next, the obtained solution was cooled to 60° C., 1 parts by mass of benzyltrimethylammonium chloride was added thereto, and the resulting mixture was heated to 100° C. and allowed to react until the solid acid value became 1 mgKOH/g or less. Further, 152 parts by mass of tetrahydrophthalic anhydride (THPAC) (c) and 100 parts by mass of carbitol acetate were added thereto, and the resulting mixture was heated to 80° C. and allowed to react for 6 hours. Thereafter, the mixture was cooled to room temperature and diluted with carbitol acetate until the solid content concentration becomes 60% by mass, thereby obtaining a THPAC-modified cresol novolac type epoxy acrylate (Epoxy Resin (3)) as Component (A2).

### Examples 1 to 5 and Comparative Examples 1 to 6

The compositions were blended according to the blend composition shown in Table 1 and kneaded with a three roll mill to prepare a photosensitive resin composition. Carbitol acetate was added thereto such that the solid content concentration became 70% by mass to obtain a photosensitive resin composition.

TABLE 1

| | | | Example | | | | | Comparative Example | | | | | |
|---|---|---|---|---|---|---|---|---|---|---|---|---|---|
| Component | | Material | 1 | 2 | 3 | 4 | 5 | 1 | 2 | 3 | 4 | 5 | 6 |
| A | A1 | Epoxy resin (1) | 13.55 | 13.55 | 13.55 | 13.55 | 0.00 | 13.55 | 13.55 | 13.55 | 13.55 | 13.55 | 13.55 |
| | A2 | Epoxy resin (2) | 20.35 | 20.35 | 20.35 | 20.35 | 0.00 | 20.35 | 20.35 | 20.35 | 20.35 | 20.35 | 20.35 |
| | A3 | Epoxy resin (3) | 0.00 | 0.00 | 0.00 | 0.00 | 33.90 | 0.00 | 0.00 | 0.00 | 0.00 | 0.00 | 0.00 |

| | | | | | | | | | | | | |
|---|---|---|---|---|---|---|---|---|---|---|---|---|
| B | Irgacure 907 | 0.77 | 0.77 | 0.77 | 0.00 | 0.77 | 0.77 | 0.00 | 0.77 | 0.77 | 0.77 | 0.77 |
| | DETX | 0.04 | 0.04 | 0.04 | 0.04 | 0.04 | 0.04 | 0.04 | 0.04 | 0.04 | 0.04 | 0.04 |
| | Irgacure 819 | 0.00 | 0.00 | 0.00 | 0.77 | 0.00 | 0.00 | 0.77 | 0.00 | 0.00 | 0.00 | 0.00 |
| C | IXE 500 | 0.43 | 0.00 | 0.00 | 0.00 | 0.00 | 0.00 | 0.00 | 0.00 | 0.00 | 0.00 | 0.00 |
| | IXE 800 | 0.00 | 0.43 | 0.00 | 0.00 | 0.00 | 0.00 | 0.00 | 0.00 | 0.00 | 0.00 | 0.00 |
| | IXEPLAS-A2 | 0.00 | 0.00 | 0.43 | 0.43 | 0.43 | 0.00 | 0.00 | 0.00 | 0.00 | 0.00 | 0.00 |
| — | IXE 300 | 0.00 | 0.00 | 0.00 | 0.00 | 0.00 | 0.00 | 0.00 | 0.00 | 0.00 | 0.00 | 0.43 |
| D | DPHA | 1.17 | 1.17 | 1.17 | 1.17 | 1.17 | 1.17 | 1.17 | 1.17 | 1.17 | 1.17 | 1.17 |
| E | Phthalocyanine-based | 4.89 | 4.89 | 4.89 | 4.89 | 4.89 | 4.89 | 4.89 | 4.89 | 4.89 | 4.89 | 4.89 |
| | pigment | | | | | | | | | | | |
| F | B34 | 11.37 | 11.37 | 11.37 | 11.37 | 11.37 | 11.37 | 11.37 | 11.37 | 11.37 | 11.37 | 11.37 |
| | SFP20M | 31.27 | 31.27 | 31.27 | 31.27 | 31.27 | 31.27 | 31.27 | 31.27 | 31.27 | 31.27 | 31.27 |
| | SG-95 | 0.00 | 0.00 | 0.00 | 0.00 | 0.00 | 0.00 | 0.00 | 0.43 | 0.00 | 0.00 | 0.00 |
| | ZR-30AL | 0.00 | 0.00 | 0.00 | 0.00 | 0.00 | 0.00 | 0.00 | 0.00 | 0.43 | 0.00 | 0.00 |
| | BL103 | 0.00 | 0.00 | 0.00 | 0.00 | 0.00 | 0.00 | 0.00 | 0.00 | 0.00 | 0.43 | 0.00 |
| G | Curing agent | 15.90 | 15.90 | 15.90 | 15.90 | 15.90 | 15.90 | 15.90 | 15.90 | 15.90 | 15.90 | 15.90 |
| I | Melamine | 0.26 | 0.26 | 0.26 | 0.26 | 0.26 | 0.26 | 0.26 | 0.26 | 0.26 | 0.26 | 0.26 |

The numerical values in the table are % by mass of the solid content of each component based on the total solid content of the photosensitive resin composition.

In addition, the details of each material in Table 1 are as follows.

Epoxy Resins (1) to (3) are the epoxy resins containing an acid-modified vinyl group (1) to (3) obtained in Synthesis Examples 1 to 3, respectively.

Irgacure 907: 2-methyl-1-(4-methylthiophenyl)-2-morpholinopropan-1-one (manufactured by BASF Inc., trade name), an alkylphenone-based photopolymerization initiator

DETX: KAYACURE DETX-S, 2,4-diethylthioxanthone (manufactured by Nippon Kayaku Co., Ltd., trade name), a compound having a thioxanthone skeleton (thioxanthone-based photopolymerization initiator)

Irgacure 819: bis (2,4,6-trimethylbenzoyl)phenylphosphine oxide (manufactured by BASF Inc., trade name), an acylphosphine oxide-based photopolymerization initiator

IXE 500: anion scavenger containing Bi (manufactured by Toagosei Co., Ltd., trade name, average particle diameter: 1.5 μm, and content of Bi compound: 100% by mass)

IXE 800: anion scavenger containing Zr (manufactured by Toagosei Co., Ltd., trade name, average particle diameter: 2.0 μm, and content of Zr compound: 100% by mass)

IXEPLAS-A2: amphoteric scavenger containing Zr, Mg, and Al (manufactured by Toagosei Co., Ltd., trade name, average particle diameter: 0.2 μm, and content of Zr compound: 20 to 30% by mass)

IXE 300: cation scavenger (manufactured by Toagosei Co., Ltd., a cation scavenger which does not contain any of Zr, Bi, Mg and Al)

DPHA: dipentaerythritol hexaacrylate (manufactured by Nippon Kayaku Co., Ltd., trade name)

Phthalocyanine-based pigment: phthalocyanine-based pigment (manufactured by Sanyo Color Works, Ltd.)

B34: barium sulfate particles (manufactured by Sakai Chemical Industry Co., Ltd., trade name, average particle diameter: 0.3 μm)

SFP20M: silica particles (Denki Kagaku, Kogyo. Co., Ltd., trade name, average particle diameter: 0.3 μm)

SG-95: talc (Nippon Talc Co., Ltd., trade name, average particle diameter: 2.5 μm, compound having no ion capturing function)

ZR-30AL: zirconia particles (Nissan Chemical Industries, Ltd., trade name, average particle diameter: 50 μm, compound having no ion capturing function)

BL103: aluminum hydroxide particles (Nippon Light Metal Co., Ltd., trade name, average particle diameter: 10 μm)

Curing agent: YX4000X (manufactured by Mitsubishi Chemical Corporation, trade name, biphenyl type epoxy resin)

Melamine: manufactured by Nissan Chemical Industries, Ltd.

Next, each evaluation was carried out under the following conditions by using the photosensitive resin composition obtained above. The evaluation results are shown in Table 2.

### [Preparation of Test Specimen]

After the photosensitive resin compositions in the Examples and the Comparative Examples were applied to a copper clad laminate substrate (MCL-E-67, manufactured by Hitachi Chemical Co., Ltd.) having a thickness of 0.6 mm by a screen printing method such that the film thickness after drying was 35 μm, the photosensitive resin compositions were dried at 80° C. for 20 minutes by using a hot air circulation type dryer. Next, a negative mask having a predetermined pattern (pattern with a hole diameter of 50 μm and a distance between the centers of the holes of 50 μm) was brought into close contact with the application film and exposed with an exposure amount of 600 mJ/cm² by using an ultraviolet exposure apparatus. Thereafter, the unexposed parts were dissolved and developed by carrying out spray development with 1% by mass of an aqueous sodium carbonate solution for 60 seconds at a pressure of 1.765×10⁵ Pa. Next, the photosensitive resin composition was exposed with an exposure amount of 1,000 mJ/cm² by using an ultraviolet exposure apparatus and heated at 150° C. for 1 hour, thereby preparing a test specimen having a permanent mask resist.

### [Resist Shape]

The test specimen was cast and cured sufficiently by using an epoxy resin (jER 828, manufactured by Mitsubishi Chemical Corporation, trade name) and triethylenetetramine as a curing agent, and then polished with a polishing machine (Refine Polisher (manufactured by Refine Tec Ltd.)) to cut out the cross section of the pattern, and the resist shape was observed by a metallurgical microscope. The resist shape was determined based on the following criteria.

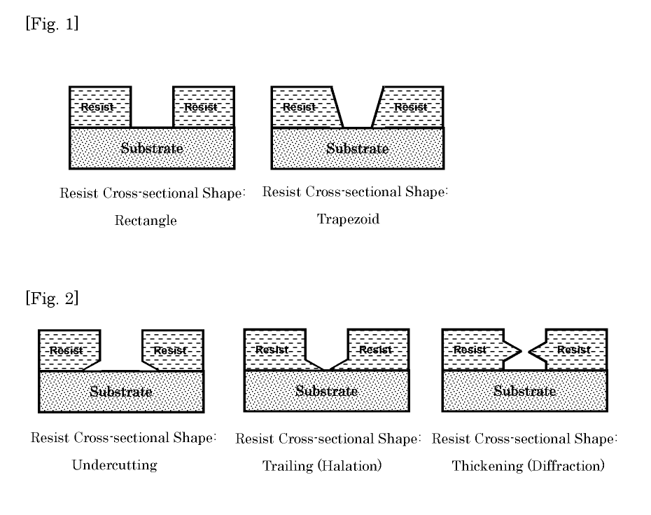

A: for the resist shape, neither undercutting nor defects in the upper part of the resist were confirmed, and the linearity in the contours of the pattern was good (see FIG. 1).

B: for the resist shape, undercutting and defects in the upper part of the resist were confirmed, and the linearity in the contours of the pattern was poor (see FIG. 2).

### [Adhesion]

After the photosensitive resin compositions in the Examples and the Comparative Examples were applied to a copper foil (manufactured by Nippon Denkai, Ltd.) having a thickness of 35 μm by a screen printing method such that the film thickness after drying was 35 μm, the photosensitive resin compositions were dried at 80° C. for 20 minutes by using a hot air circulation type dryer. Subsequently, the negative mask was brought into close contact with the application film, and the photosensitive layer was exposed with an exposure amount of 200 mJ/cm² by using a parallel exposure machine (manufactured by HITECH Corporation, trade name: HTE-51025). Thereafter, the unexposed parts were dissolved and developed by carrying out spray development with 1% by mass of an aqueous sodium carbonate solution for 60 seconds at a pressure of 1.765×10⁵ Pa. Next, the photosensitive resin composition was exposed with an exposure amount of 1,000 mJ/cm² by using an ultraviolet exposure apparatus and heated at 150° C. for 1 hour, thereby preparing a test specimen with a permanent mask resist provided on the copper foil. The surface of the obtained test specimen provided with the permanent mask resist was bonded to a copper clad laminate (MCL-E-67, manufactured by Hitachi Chemical Co., Ltd.) by using and curing an adhesive (manufactured by Nichiban Co., Ltd., trade name: Araldite). After the test specimen was left to stand for 12 hours, one end of the copper foil was peeled off by 10 mm. Subsequently, the laminate was fixed, the peeled copper foil was pinched with a gripper, and the load (peel strength) when the copper foil was pulled and peeled off at room temperature in a thickness direction (vertical direction) of the copper foil at a tension speed of 50 mm/min was measured 8 times, and the average value was calculated from the values measured 8 times and used as an index of the adhesive strength. In addition, the peel strength was evaluated in accordance with JIS C 5016 (1994-peel strength of a conductor) and evaluated under the following criteria. Furthermore, in the present specification, room temperature indicates 25° C.

A: the peel strength is larger than 0.5 kN/mm

B: the peel strength ranges from 0.3 to 0.5 kN/mm

C: the peel strength is less than 0.3 kN/mm

### [Melt Viscosity (Fluidity)]

A photosensitive resin composition was applied onto a polyethylene terephthalate (PET) film so as to have a circular shape with a diameter of 2.5 cm and a thickness of 100 to 1,000 μm, and the solvent of the composition was evaporated, thereby preparing a test specimen in a state where the composition did not flow even though the test specimen was allowed to stand still. Thereafter, the melt viscosity of the test specimen was measured by using a rheometer (manufactured by Thermo Scientific Co., Ltd., trade name: Rheostress 6000).

A: the viscosity at 100° C. is less than 100 Pa/s

B: the viscosity at 100° C. is 100 Pa/s or more

### [Insulation (Electrical Insulation)]

A test specimen was formed in the same manner as described in the above [Preparation of Test Specimen], except that a bismaleimide triazine substrate on which a comb electrode (line/space=10 μm/10 μm) was formed was used instead of the copper clad laminate substrate, and the test specimen was exposed to the conditions of 135° C., 85%, and 5 V. Thereafter, the degree of occurrence of migration was observed by a 100 times metallurgical microscope and evaluated according to the following criteria.

A: even though more than 200 hours elapsed, the resistance value did not drop to 10⁻⁶Ω or less without migration occurring in the permanent mask resist.

B: from 100 hours or more and less than 200 hours, the resistance value did not drop to 10⁻⁶Ω or less without migration occurring in the permanent mask resist.

C: in less than 100 hours, migration occurred in the permanent mask resist, and the resistance value dropped to 10⁻⁶Ω or less.

### [Soldering Heat Resistance]

A water soluble flux was applied to a test specimen prepared in the same manner as described in the [Preparation of Test Specimen], and the water soluble flux was immersed in a solder bath at 265° C. for 10 seconds. After repeating six cycles with the above procedure as one cycle, the appearance of the permanent mask resist was observed by the unaided eye and evaluated according to the following criteria.

3: there was no change in appearance within 30 cm×30 cm of the permanent mask resist.

2: 1 to 5 lifting or blistering of the application film occurred within 30 cm×30 cm of the permanent mask resist.

1: 6 or more of lifting or blistering of the application film occurred within 30 cm×30 cm of the permanent mask resist.

### [Crack Resistance]

A test specimen prepared in the same manner as described in the [Preparation of Test Specimen] was subjected to repetition of 1,000 cycles with one cycle of −65° C. for 30 minutes/(normal temperature: 25° C.)/150° C. for 30 minutes, and then the appearance of the permanent mask resist was observed by the unaided eye and evaluated according to the following criteria.

3: there was no change in appearance within 30 cm×30 cm of the permanent mask resist.

2: 1 to 5 lifting or blistering of the application film occurred within 30 cm×30 cm of the permanent mask resist.

1: 6 or more lifting or blistering of the application film occurred within 30 cm×30 cm of the permanent mask resist.

### [Solvent Resistance]

After confirming whether there was any abnormality in the appearance of the permanent mask resist by immersing a test specimen prepared in the same manner as described in the [Preparation of Test Specimen] in isopropyl alcohol at room temperature (25° C., hereinafter, the same will apply) for 30 minutes, a peeling test was carried out by a cellophane tape.

3: There was no abnormality in the appearance of the permanent mask resist, and peeling did not occur.

2: A slight change occurred in the appearance of the permanent mask resist.

1: There was abnormality in the appearance of the permanent mask resist or peeling occurred.

### [Acid Resistance]

After confirming whether there was any abnormality in the appearance of the permanent mask resist by immersing a test specimen prepared in the same manner as described in the [Preparation of Test Specimen] in 10% by mass of an aqueous hydrochloric acid solution at room temperature for 30 minutes, a peeling test was carried out by a cellophane tape.

3: There was no abnormality in the appearance of the permanent mask resist, and peeling did not occur.

2: A slight change occurred in the appearance of the permanent mask resist.

1: There was abnormality in the appearance of the permanent mask resist or peeling occurred.

### [Alkali Resistance]

After confirming whether there was any abnormality in the appearance of the permanent mask resist by immersing a test specimen prepared in the same manner as described in the [Preparation of Test Specimen] in 5% by mass of an aqueous sodium hydroxide solution at room temperature for 30 minutes, a peeling test was carried out by a cellophane tape.

3: There was no abnormality in the appearance of the permanent mask resist, and peeling did not occur.

2: A slight change occurred in the appearance of the permanent mask resist.

1: There was abnormality in the appearance of the permanent mask resist or peeling occurred.

TABLE 2

| | Example | | | | | Comparative Example | | | | | |
|---|---|---|---|---|---|---|---|---|---|---|---|
| Characteristics | 1 | 2 | 3 | 4 | 5 | 1 | 2 | 3 | 4 | 5 | 6 |
| Resist shape | A | A | A | A | A | B | B | B | B | B | B |
| Adhesion | B | A | A | A | B | C | C | C | C | C | C |
| Melt viscosity | A | A | A | A | A | B | B | B | B | B | B |
| Insulation | B | B | A | A | A | C | C | C | C | C | C |

From Table 2, the photosensitive resin composition of the present exemplary aspect in Examples 1 to 5 exhibited excellent performance in terms of resist shape, adhesion, melt viscosity (fluidity), and insulation, and was also evaluated as “3” in the evaluation of soldering heat resistance, crack resistance, solvent resistance, acid resistance, and alkali resistance. As described above, it was confirmed that the photosensitive resin composition of the present exemplary aspect exhibited excellent performance in all characteristics, and in particular, the photosensitive resin composition is a composition that may be suitably used as a permanent mask resist. In contrast, the resin compositions in Comparative Examples 1 to 6 could not obtain excellent effects, particularly in terms of adhesion and insulation.

### Examples 6 to 10 and Comparative Examples 7 to 12

Each of the photosensitive resin compositions in Examples 1 to 5 and Comparative Examples 1 to 6 prepared at the blending ratios shown in Table 1 was diluted with methyl ethyl ketone, applied onto a polyethylene terephthalate (PET) film, and dried at 90° C. for 10 minutes, thereby forming a photosensitive layer formed of a photosensitive resin composition having a thickness of 25 μm. Further, a cover film was laminated thereon to prepare dry films in Examples 6 to 10 and Comparative Examples 7 to 12, respectively.

### [Evaluation of Dry Film]

The cover film was peeled off from the dry film obtained above, the dry film was thermally laminated on an entire surface of a copper foil substrate, and then subsequently exposed in the same manner as described in the [Preparation of Test Specimen], thereby preparing a test specimen having a permanent mask resist.

The same evaluation as in Example 1 was carried out by using the obtained test specimen. The results are shown in Table 3.

TABLE 3

| | Example | | | | | Comparative Example | | | | | |
|---|---|---|---|---|---|---|---|---|---|---|---|
| Characteristics | 6 | 7 | 8 | 9 | 10 | 7 | 8 | 9 | 10 | 11 | 12 |
| Resist shape | A | A | A | A | A | B | B | B | B | B | B |
| Adhesion | B | A | A | A | B | C | C | C | C | C | C |
| Melt viscosity | A | A | A | A | A | B | B | B | B | B | B |
| Insulation | B | B | A | A | A | C | C | C | C | C | C |

From the results shown in Table 3, the dry film of the present exemplary aspect in Examples 6 to 10 exhibited excellent performance in terms of resist shape, adhesion, melt viscosity (fluidity), and insulation, and was also evaluated as “3” in the evaluation of soldering heat resistance, crack resistance, solvent resistance, acid resistance, and alkali resistance. As described above, it was confirmed that the dry film of the present exemplary aspect exhibited excellent performance in all characteristics, and in particular, the photosensitive resin composition may be suitably used in the preparation of a permanent mask resist. In contrast, the dry film in Comparative Examples 7 to 12 could not obtain excellent effects, particularly in terms of adhesion and insulation.

1. A photosensitive resin composition comprising:
(A) an acid-modified vinyl group-containing epoxy resin;
(B) a photopolymerization initiator; and
(C) an ion scavenger having at least one selected from the group consisting of Zr, Bi, Mg, and Al; and
(D) a photopolymerizable compound.

2. The photosensitive resin composition according to claim 1, wherein the component (A) contains (Al) at least one acid-modified vinyl group-containing epoxy resin obtained by using a bisphenol novolac type epoxy resin (a1), and (A2) at least one acid-modified vinyl group-containing epoxy resin obtained by using an epoxy resin (a2) different from the epoxy resin (a1).

3. The photosensitive resin composition according to claim 2, wherein the epoxy resin (a2) is at least one selected from the group consisting of a novolac type epoxy resin, a bisphenol A type epoxy resin, a bisphenol F type epoxy resin, and a triphenol methane type epoxy resin.

4. The photosensitive resin composition according to claim 2, wherein the acid-modified vinyl group-containing epoxy resins (A1) and (A2) are resins obtained by allowing a saturated or unsaturated group-containing polybasic acid anhydride (c) to react with resins (A1′) and (A2′) obtained by allowing a vinyl group-containing monocarboxylic acid (b) to react with the epoxy resins (a1) and (a2), respectively.

5. The photosensitive resin composition according to claim 2, wherein the bisphenol novolac type epoxy resin (a1) has a structural unit represented by the following general formula (I) or (II): 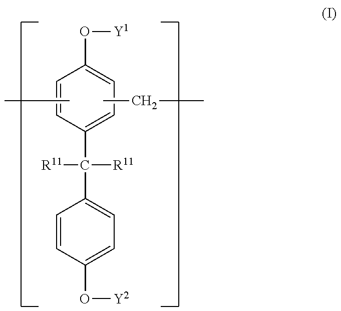
wherein R¹¹ represents a hydrogen atom or a methyl group, and Y¹ and Y² each independently represent a hydrogen atom or a glycidyl group, provided that plural R¹¹'s are the same or different and at least one of Y¹ and Y² represents a glycidyl group: 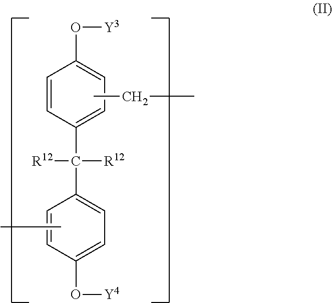
wherein R¹² represents a hydrogen atom or a methyl group, and Y³ and Y⁴ each independently represent a hydrogen atom or a glycidyl group, provided that plural R¹²'s are the same or different and at least one of Y³ and Y⁴ represents a glycidyl group.

6. The photosensitive resin composition according to claim 2, wherein the bisphenol novolac type epoxy resin (a1) has the structural unit represented by general formula (I), and the epoxy resin (a2) is a bisphenol A type epoxy resin or a bisphenol F type epoxy resin, which contains a structural unit represented by the following general formula (IV): 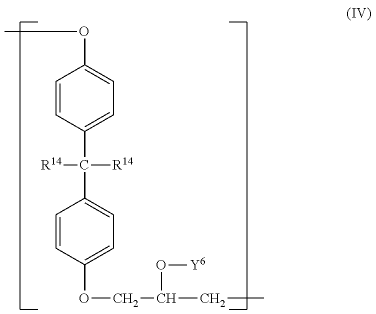
wherein R¹⁴ represents a hydrogen atom or a methyl group, Y⁶ represents a hydrogen atom or a glycidyl group, and plural R¹⁴'s are the same or different.

7. The photosensitive resin composition according to claim 1, wherein the component (A) contains at least one acid-modified vinyl group-containing epoxy resin (A2) obtained by using an epoxy resin (a2) different from a bisphenol novolac type epoxy resin (a1).

8. The photosensitive resin composition according to claim 7, wherein the acid-modified vinyl group-containing epoxy resin (A2) is a resin obtained by allowing a saturated or unsaturated group-containing polybasic acid anhydride (c) to react with a resin (A2′) obtained by allowing a vinyl group-containing monocarboxylic acid (b) to react with the epoxy resin (a2).

9. The photosensitive resin composition according to claim 7, wherein the epoxy resin (a2) is a novolac type epoxy resin having a structural unit represented by general formula (III): 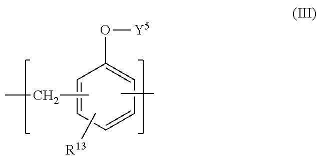
wherein R¹³ represents a hydrogen atom or a methyl group, and Y⁵ represents a hydrogen atom or a glycidyl group.

10. The photosensitive resin composition according to claim 1, wherein the photopolymerization initiator (B) is at least one selected from the group consisting of an alkylphenone-based photopolymerization initiator, a compound having a thioxanthone skeleton (thioxanthone-based photopolymerization initiator), and an acylphosphine oxide-based photopolymerization initiator.

11. The photosensitive resin composition according to claim 1, wherein the ion scavenger (C) is at least one selected from the group consisting of an inorganic ion exchanger that captures cations, an inorganic ion exchanger that captures anions, and an inorganic ion exchanger that captures cations and anions.

12. The photosensitive resin composition according to claim 1, wherein the photopolymerizable compound (D) is a compound containing a (meth)acryloyl group.

13. The photosensitive resin composition according to claim 1, further comprising (E) a pigment.

14. The photosensitive resin composition according to claim 1, further comprising (F) an inorganic filler.

15. The photosensitive resin composition according to claim 1, wherein the contents of the acid-modified vinyl group-containing epoxy resin (A), the photopolymerization initiator (B), the ion scavenger (C), and the photopolymerizable compound (D) are from 20 to 80% by mass, from 0.2 to 15% by mass, from 0.1 to 10% by mass, and from 0.1 to 10% by mass, respectively, based on a total solid content in the photosensitive resin composition.

16. A dry film comprising a carrier film and a photosensitive layer prepared by using the photosensitive resin composition according to claim 1.

17. A printed wiring board comprising a permanent mask resist formed by the photosensitive resin composition according to claim 1.

18. The printed wiring board according to claim 17, wherein the permanent mask resist has a thickness of 10 μm or more.

19. A method for producing a printed wiring board, the method comprising, in the following order:
providing a photosensitive layer by using the photosensitive resin composition according to claim 1;
forming a resist pattern by using the photosensitive layer; and
curing the resist pattern to thereby form a permanent mask resist.

20. A method for producing a printed wiring board, the method comprising, in the following order:
providing a photosensitive layer by using the photosensitive resin composition according to the dry film according to claim 16;
forming a resist pattern by using the photosensitive layer; and
curing the resist pattern to thereby form a permanent mask resist.
